(19) United States
(12) Patent Application Publication
(10) Pub. No.: US 2024/0394436 A1
(43) Pub. Date: Nov. 28, 2024

(54) Battery Formation Diagnostics Using Real-Time Expansion

(71) Applicant: THE REGENTS OF THE UNIVERSITY OF MICHIGAN, Ann Arbor, MI (US)

(72) Inventors: Anns STEFANOPOULOU, Ann Arbor, MI (US); Jason B. SIEGEL, Ann Arbor, MI (US); Everardo OLIDE, Ann Arbor, MI (US); Andrew WENG, Ann Arbor, MI (US)

(21) Appl. No.: 18/673,707

(22) Filed: May 24, 2024

Related U.S. Application Data
(60) Provisional application No. 63/469,269, filed on May 26, 2023.

(51) Int. Cl. G06F 30/20; H01M 10/0525; H01M 10/44

(52) U.S. Cl. CPC G06F 30/20; H01M 10/0525; H01M 10/446

(57) ABSTRACT

A method for manufacturing an electrochemical cell including an anode, an electrolyte, and a cathode including cations that move from the cathode to the anode during a charging phase is disclosed. The method comprises: (a) selecting at least one cell component from electrolyte materials, cathode active materials, and anode active materials, the at least one cell component causing degradation of the cell; (b) selecting a formation protocol including: (i) a formation charging phase for creating a formed cell from a cell structure, and (ii) an aging phase for aging the formed cell; (c) calculating a solid electrolyte interphase growth process based on the formation protocol and the at least one cell component using a solid electrolyte interphase growth model that predicts consumption of the cations and expansion of the cell; and (d) determining a property of the cell based on the calculated solid electrolyte interphase growth process.

### CROSS-REFERENCES TO RELATED APPLICATIONS

This application is based on, claims benefit of, and claims priority to U.S. Application No. 63/469,269 filed on May 26, 2023, which is hereby incorporated by reference herein in its entirety for all purposes.

### STATEMENT REGARDING FEDERALLY SPONSORED RESEARCH

Not Applicable.

### BACKGROUND OF THE INVENTION

### 1. Field of the Invention

This invention relates to electrochemical devices, such as lithium ion batteries and lithium metal batteries. This invention also relates to methods for making such electrochemical devices.

### 2. Description of the Related Art

Every commercial lithium-ion battery undergoes formation as the last step in battery manufacturing. During formation, the battery is charged for the first time to form the solid-electrolyte interphase (SEI), a passivating film that stabilizes the electrode-electrolyte interface, enabling long battery lifetimes. The formation process is time and capital-intensive, motivating battery manufacturers to develop new formation recipes to decrease formation time while preserving battery lifetime and safety. Yet, despite its importance, methods for characterizing the formation process remain limited since the complex electrochemistry occurring during battery formation is not easily observed by external measurements of battery voltage and current.

What is needed therefore is improved methods and models for characterizing solid-electrolyte interphase formation such that batteries having improved properties can be developed by battery manufacturers.

### SUMMARY OF THE INVENTION

The present disclosure meets the foregoing needs by providing devices and methods that enable the quantification of solid-electrolyte interphase thickness in real-time during the formation process. The solid-electrolyte interphase thickness is an essential performance parameter that can then be leveraged to optimize battery formation protocols.

In one aspect, the present disclosure provides a method for manufacturing an electrochemical cell including an anode, an electrolyte, and a cathode including cations that move from the cathode to the anode during a charging phase of each of a plurality of cell cycles, wherein the cell undergoes degradation that results in loss of cation inventory during one or more charging phases of the cell cycles. The method comprises: (a) selecting at least one cell component selected from the group consisting of electrolyte materials, cathode active materials, and anode active materials, the at least one cell component causing the degradation of the cell; (b) selecting a formation protocol including: (i) a formation charging phase for creating a formed battery cell from a battery cell structure, and (ii) an aging phase for aging the formed battery cell; (c) calculating a solid electrolyte interphase (SEI) growth process based on the formation protocol and the at least one cell component using a solid electrolyte interphase growth model that predicts consumption of the cations and expansion of the cell; and (d) determining a property of the electrochemical cell based on the calculated solid electrolyte interphase growth process, wherein the property is selected from the group consisting of predicted end of life, capacity loss, resistance growth, gas generation, and electrode current collector dissolution.

In another aspect, the present disclosure provides a method for monitoring real-time expansion of an electrochemical cell including an anode, an electrolyte, and a cathode including cations that move from the cathode to the anode during a charging phase of each of a plurality of cell cycles, wherein the cell undergoes degradation that results in loss of cation inventory during one or more charging phases of the cell cycles. The method comprises: (a) selecting at least one cell component selected from the group consisting of electrolyte materials, cathode active materials, and anode active materials, the at least one cell component causing the degradation of the cell; (b) calculating a solid electrolyte interphase (SEI) growth process based on the at least one cell component using a solid electrolyte interphase growth model that predicts consumption of the cations and expansion of the cell; and (c) determining real-time expansion of the electrochemical cell based on the calculated solid electrolyte interphase growth process.

In yet another aspect, the present disclosure provides a method for predicting a property of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolyte materials, cathode active materials, and anode active materials, the at least one cell component causing the degradation of the cell; (b) calculating a solid electrolyte interphase (SEI) growth process based on the at least one cell component using a solid electrolyte interphase growth model that predicts consumption of the cations and expansion of the cell; and (c) determining a property of the electrochemical cell based on the calculated solid electrolyte interphase growth process, wherein the property is selected from the group consisting of predicted end of life, capacity loss, resistance growth, gas generation, and electrode current collector dissolution.

In still another aspect, the present disclosure provides a method in a data processing system comprising at least one processor and at least one memory, the at least one memory comprising instructions executed by the at least one processor to implement an electrochemical cell property prediction system, wherein the electrochemical cell includes an anode, an electrolyte, and a cathode including cations that move from the cathode to the anode during a charging phase of each of a plurality of cell cycles, wherein the cell undergoes degradation that results in loss of cation inventory during one or more charging phases of the cell cycles. The method comprises: (a) receiving a selection of at least one cell component selected from the group consisting of electrolyte materials, cathode active materials, and anode active materials, the at least one cell component causing the degradation of the cell; (b) calculating a solid electrolyte interphase (SEI) growth process based on the at least one cell component using a solid electrolyte interphase growth model that predicts consumption of the cations and expansion of the cell; and (c) determining a property of the electrochemical cell based on the calculated solid electrolyte interphase growth process.

Devices and methods are provided for measuring the growth of the solid-electrolyte interphase during the formation of a lithium-ion battery. The devices comprise a pre-formation lithium-ion battery cell and an expansion sensing platform. The pre-formation lithium-ion battery cell comprises a cathode, an anode, a separator, and an electrolyte. The pre-formation lithium-ion battery cell has not yet undergone the formation process, which is the first time a battery is charged and the last step of the battery manufacturing process. The expansion sensing platform comprises an expansion sensor, a battery expansion fixture, and a data logger. The method comprises using the expansion sensing platform to measure the expansion of the pre-formation lithium ion battery during the formation process. The expansion measurements are logged continuously during formation, enabling real-time monitoring of the solid-electrolyte interphase thickness during battery formation. The method can be extended to monitor solid-electrolyte interphase growth after battery formation has been completed, i.e., during a cycle life test or a calendar aging test. The method can also include mathematical models and methods for estimating solid-electrolyte interphase material properties, such as densities, reaction rates, and porosities, based on the thickness measurements.

These and other features, aspects, and advantages of the present invention will become better understood upon consideration of the following detailed description, drawings and appended claims.

### BRIEF DESCRIPTION OF THE DRAWINGS

FIG. 1 is a schematic of a lithium ion battery.

FIG. 1A is a schematic of a lithium metal battery.

FIG. 1B shows experimentally-measurable macroscopic signals from the battery formation and aging process. Panel (A) Electrochemical (voltage and current) signal is shown in black. These signals are obtainable directly from the equipment used for battery formation cycling. Macroscopic cell thickness expansion is shown in red. Panel (B) Example image of the multi-layer stacked pouch cells similar to the one used for this work. Panel (C) An expansion fixture instrumented with a linear displacement sensor enabling real-time cell thickness expansion during the formation process.

FIG. 2 shows consolidating SEI reaction pathways during charging, discharging and rest. S: solvent molecule, e.g. ethylene carbonate (EC) or vinylene carbonate (VC). SEI^{*}: newly SEI formed at the electrode-SEI interface. Li⁺: solvated lithium ions from the electrolyte. Li⁰: neutral lithium intercalated into the negative electrode.

FIG. 3 shows a zero-dimensional ‘dual-tank’ formation modeling framework. Panel (A) Model components and key state variables. At each electrode i=(n, p), the lithium stoichiometry θᵢ is tracked and used to update the electrode equilibrium surface potentials Uᵢ and volumetric expansions vᵢ. Electrode surface overpotentials are represented by R-RC elements which capture both charge-transfer and solid-state diffusion dynamics. The total applied current density jₐₚₚ passes through the positive electrode. However, at the negative electrode, the current is split between the intercalation current density jᵢₙₜ and the SEI current density j_{SEI}. SEI build-up leads to SEI thickness growth, denoted by δ_{SEI}. Panel (B) Electrode equilibrium potential functions and volumetric expansion functions assumed for this work, adapted from Mohtat et al. [Ref. 10]. The markers indicate the initial conditions (I.C.s) corresponding to the state of the cell before formation begins.

FIG. 4 shows a schematic of the SEI growth boosting mechanism. Panel (A) During lithiation (charging), SEI growth rate is boosted due to SEI fracture as the negative electrode particles expand. During resting and delithiation (discharging), the SEI growth rate is de-boosted to the nominal rate as the SEI film ‘self-heals.’ Panel (B) Boosting dynamics is represented by B(t) which modifies the effective SEI diffusivity D_{SEI}. Elyte: electrolyte.

FIG. 5 shows homogenized representation of multi-species SEI reaction kinetics. Panel (A) Heterogeneous representation. Panel (B) Homogenized representation. Variables with bars indicate volume-averaged (homogenized) quantities. In the homogenized representation, SEI reactions occur in parallel but the reaction kinetics are coupled through a homogenized medium represented by homogenized diffusivities for each reacting species, r, D̅_{SEI,r}, and the total SEI thickness. In the heterogeneous case, there are (nᵣ×nᵣ) diffusivities, where nᵣ is the number of reacting species. In the homogeneous case, the number of diffusivities is reduced to only nᵣ elements.

FIG. 6 shows SEI reaction and full cell expansion dynamics during the first formation charge cycle. Panel (A) Full cell voltage, electrode potentials, and SEI reaction potentials. Panel (B) Applied current and SEI reaction currents. Panel (C) Full cell thickness expansion, including both reversible expansion from electrode intercalation and irreversible expansion from SEI components. EC: ethylene carbonate. VC: vinylene carbonate. (1) Negligible SEI growth occurs before the first charge cycle due to reaction limitations. (2) VC reduces first, followed by (3) EC reduction. (4) Expansion rate of lithiated graphite slows down at mid-SOCs, causing a (5) decrease in the EC reduction current as a result of the SEI growth boosting/de-boosting mechanism.

FIG. 7 shows reaction-diffusion and solvent consumption dynamics during the first formation charge cycle. Panel (A) Applied current and SEI reaction currents. Panel (B) Breakdown of limiting current for EC. Panel (C) Breakdown of limiting current for VC. Panel (D) Bulk solvent concentration. EC: ethylene carbonate. VC: vinylene carbonate. (1) Negligible SEI growth occurs before the first charge due to reaction limitations. (2) The EC and VC reduction processes are both initially reaction-limited. (3) Transition from reaction-limited to diffusion-limited regimes for both the EC and VC reduction reactions. (4) Decrease in VC reaction current density due to the coupling between EC and VC diffusivities introduced by the multi-species reaction model extension. (5) Surge in diffusion-limited current due to the effect of the boosted SEI growth mechanism. (6) VC consumption rate plateaus due to the decrease in VC reaction current density.

FIG. 8 shows a demonstration of SEI growth rate boosting during charging and de-boosting during resting and discharging. A simulation was configured to alternate between cycling and calendar aging, illustrating the boosted SEI growth rate during cycling charge events. Panel (A) Full cell voltage and electrode potentials. Panel (B) Positive and negative electrode volumetric expansion functions. Panel (C) Boost function B(t) plotted against the boosting input term γ(dvₙ/dt). Panel (D) Comparison of SEI thickness growth rates on cycling versus calendar aging. EC: ethylene carbonate. VC: vinylene carbonate. (1) Step transitions in the boost function due to the piecewise-linear construction of the negative electrode expansion function. (2) Negative electrode contracts slightly during rest since lithium continues to deintercalate from the negative electrode to form the SEI. (3) The de-boosting process is assumed to be much slower than the boosting process for this work. (4) No boosting occurs during discharge due to the assumption that the SEI maintains physical contact with the negative electrode particles so no new reaction surfaces are exposed.

FIG. 9 shows a model comparison against experimental data. The dataset consists of three formation charge-discharge cycles, a reference performance test (RPT) sequence, and formation aging at 100% SOC. Panel (A) Full cell voltage. Panel (B) Thickness expansion.

FIG. 10 shows a model vs measured Coulombic efficiency (CE). First cycle efficiency (FCE) is defined as the CE of the first formation charge cycle.

FIG. 11 shows modeled vs experimental dQ/dV trace during the formation charge cycle. Panel (A) dQ/dV vs V, where V is the full cell voltage. Panel (B) dQ/dUₙ vs Uₙ, where Uₙ is the negative electrode equilibrium potential.

FIG. 12 shows lithium stoichiometry and electrode potential maps over formation cycling, RPT, and formation aging. Panel (A) Positive and negative electrode lithium stoichiometries. Inset: expanded view of the lithium stoichiometries at the end of each discharge cycle. Panel (B) Positive and negative electrode equilibrium potentials. Red circle: state of the system before formation. Triangles: state of the system after formation completes and the cell is discharged. Green triangle: prediction from dV/dQ fitting method on C/20 charge voltage data taken at the end of the formation process, adapted from Weng et al. [Ref. 65].

FIG. 13 shows half-cell near-equilibrium potential functions and volumetric expansion functions. These functions were adapted from Mohtat et al. [Ref. 10]. The potential functions have additionally been expanded to satisfy Eq. 43. Panel (A) Negative electrode (graphite) Uₙ and vₙ. (B) Positive electrode (NMC622) Uₚ and vₚ.

### DETAILED DESCRIPTION OF THE INVENTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. Skilled artisans will recognize the examples provided herein have many useful alternatives and fall within the scope of embodiments of the invention.

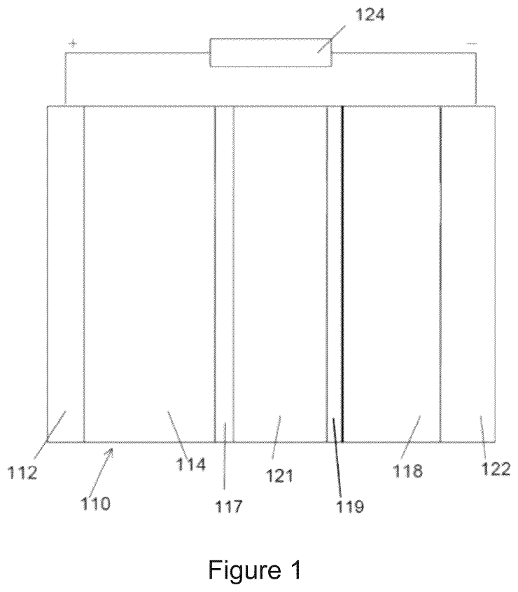

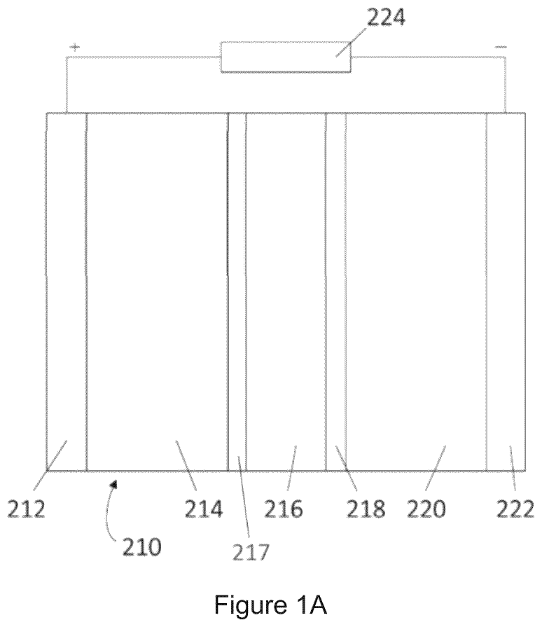

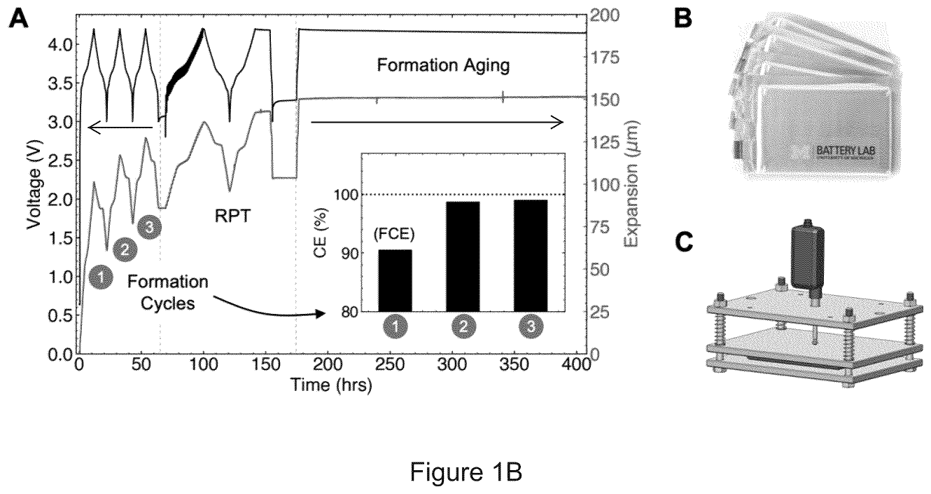

FIG. 1 shows a non-limiting example of a lithium ion battery 110 that may be manufactured according to one embodiment of the present disclosure. The lithium ion battery 110 includes a first current collector 112 (e.g., aluminum) in contact with a cathode 114. A solid state electrolyte 121 is arranged between a solid electrolyte interphase 117 on the cathode 114 and a solid electrolyte interphase 119 on an anode 118, which is in contact with a second current collector 122 (e.g., aluminum). The first and second current collectors 112 and 122 of the lithium ion battery 110 may be in electrical communication with an electrical component 124. The electrical component 124 could place the lithium ion battery 110 in electrical communication with an electrical load that discharges the battery or a charger that charges the battery.

A suitable active material for the cathode 114 of the lithium ion battery 110 is a lithium host material capable of storing and subsequently releasing lithium ions. An example cathode active material is a lithium metal oxide wherein the metal is one or more aluminum, cobalt, iron, manganese, nickel and vanadium. Non-limiting example lithium metal oxides are LiCoO₂ (LCO), LiFeO₂, LiMnO₂ (LMO), LiMn₂O₄, LiNiO₂ (LNO), LiNiₓCo_{y}O₂, LiMnₓCo_{y}O₂, LiMnₓNi_{y}O₂, LiMnₓNi_{y}O₄, LiNiₓCo_{y}Al_{z}O₂ (NCA), LiNi_{1/3}Mn_{1/3}Co_{1/3}0₂ and others. Another example of cathode active materials is a lithium-containing phosphate having a general formula LiMPO₄ wherein M is one or more of cobalt, iron, manganese, and nickel, such as lithium iron phosphate (LFP) and lithium iron fluorophosphates. The cathode can comprise a cathode active material having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The cathode active material can be a mixture of any number of these cathode active materials.

In some aspects, the cathode 114 may include a conductive additive. Many different conductive additives, e.g., Co, Mn, Ni, Cr, Al, or Li, may be substituted or additionally added into the structure to influence electronic conductivity, ordering of the layer, stability on delithiation and cycling performance of the cathode materials. Other suitable conductive additives include graphite, carbon black, acetylene black, Ketjen black, channel black, furnace black, lamp black, thermal black, conductive fibers, metallic powders, conductive whiskers, conductive metal oxides, and mixtures thereof.

A suitable active material for the anode 118 of the lithium ion battery 110 is a lithium host material capable of incorporating and subsequently releasing the lithium ion such as graphite (artificial, natural), a lithium metal oxide (e.g., lithium titanium oxide), hard carbon, a tin/cobalt alloy, or silicon/carbon. The anode active material can be a mixture of any number of these anode active materials. In some embodiments, the anode 118 may also include one or more conductive additives similar to those listed above for the cathode 114.

A suitable solid state electrolyte 121 of the lithium ion battery 110 includes an electrolyte material having the formula LiᵤReᵥM_{w}AₓO_{y}, wherein
Re can be any combination of elements with a nominal valance of +3 including La, Nd, Pr, Pm, Sm, Sc, Eu, Gd, Tb, Dy, Y, Ho, Er, Tm, Yb, and Lu;
M can be any combination of metals with a nominal valance of +3, +4, +5 or +6 including Zr, Ta, Nb, Sb, W, Hf, Sn, Ti, V, Bi, Ge, and Si;
A can be any combination of dopant atoms with nominal valance of +1, +2, +3 or +4 including H, Na, K, Rb, Cs, Ba, Sr, Ca, Mg, Fe, Co, Ni, Cu, Zn, Ga, Al, B, and Mn;
u can vary from 3-7.5;
v can vary from 0-3;
w can vary from 0-2;
x can vary from 0-2; and
y can vary from 11-12.5.
   The electrolyte material may be a lithium lanthanum zirconium oxide. The electrolyte material may have the formula Li_{6.25}La_{2.7}Zr₂Al_{0.25}O₁₂.

Another example solid state electrolyte 121 can include any combination oxide or phosphate materials with a garnet, perovskite, NaSICON, or LiSICON phase. The solid state electrolyte 121 of the lithium ion battery 110 can include any solid-like material capable of storing and transporting ions between the anode 118 and the cathode 114.

The current collector 112 and the current collector 122 can comprise a conductive material. For example, the current collector 112 and the current collector 122 may comprise molybdenum, aluminum, nickel, copper, combinations and alloys thereof or stainless steel.

Alternatively, a separator may replace the solid state electrolyte 121, and the electrolyte for the battery 110 may be a liquid electrolyte. An example separator material for the battery 110 can a permeable polymer such as a polyolefin. Example polyolefins include polyethylene, polypropylene, and combinations thereof. The liquid electrolyte may comprise a lithium compound in an organic solvent. The lithium compound may be selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf). The organic solvent may be selected from carbonate based solvents, ether based solvents, ionic liquids, and mixtures thereof. The carbonate based solvent may be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate; and the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane.

The solid electrolyte interphases 117, 119 form during a first charge of the lithium ion battery 110. To further describe the formation of a solid electrolyte interphase, a non-limiting example lithium ion battery 110 using a liquid electrolyte and having an anode comprising graphite is used in this paragraph. As lithiated carbons are not stable in air, the non-limiting example lithium ion battery 110 is assembled in its discharged state that means with a graphite anode and lithiated positive cathode materials. The electrolyte solution is thermodynamically unstable at low and very high potentials vs. Li/Li⁺. Therefore, on first charge of the lithium ion battery cell, the electrolyte solution begins to reduce/degrade on the graphite anode surface and forms the solid electrolyte interphase (SEI). There are competing and parallel solvent and salt reduction processes, which result in deposition of a number of organic and inorganic decomposition products on the surface of the graphite anode. The SEI layer imparts kinetic stability to the electrolyte against further reductions in the successive cycles and thereby ensures good cyclability of the electrode. It has been reported that SEI thickness may vary from few angstroms to tens or hundreds of angstroms. Studies suggest the SEI on a graphitic anode to be a dense layer of inorganic components close to the carbon of the anode, followed by a porous organic or polymeric layer close to the electrolyte phase.

The present invention is not limited to lithium ion batteries. In alternative embodiments, a suitable anode can comprise magnesium, sodium, or zinc. Suitable alternative cathode and electrolyte materials can be selected for such magnesium ion batteries, sodium ion batteries, or zinc ion batteries. For example, a sodium ion battery can include: (i) an anode comprising sodium ions, (ii) a solid state electrolyte comprising a metal cation-alumina (e.g., sodium-β-alumina or sodium-β″-alumina), and (iii) a cathode comprising an active material selected from the group consisting of layered metal oxides, (e.g., NaFeO, NaMnO, NaTiO, NaNiO, NaCrO, NaCoO, and NaVO) metal halides, polyanionic compounds, porous carbon, and sulfur containing materials.

FIG. 1A shows a non-limiting example of a lithium metal battery 210 that may be manufactured according to one embodiment of the present disclosure. The lithium metal battery 210 includes a current collector 212 in contact with a cathode 214. A solid state electrolyte 216 is arranged between a solid electrolyte interphase 217 on the cathode 214 and a solid electrolyte interphase 218 on an anode 220, which is in contact with a second current collector 222 (e.g., aluminum). The current collectors 212 and 222 of the lithium metal battery 210 may be in electrical communication with an electrical component 224. The electrical component 224 could place the lithium metal battery 210 in electrical communication with an electrical load that discharges the battery or a charger that charges the battery. A suitable active material for the cathode 214 of the lithium metal battery 210 is one or more of the lithium host materials listed above for battery 110, or porous carbon (for a lithium air battery), or a sulfur containing material (for a lithium sulfur battery). A suitable solid state electrolyte material for the solid state electrolyte 216 of the lithium metal battery 210 is one or more of the solid state electrolyte materials listed above for battery 110. In one embodiment, the anode 220 of the lithium metal battery 210 comprises lithium metal. In one embodiment, the anode 220 of the lithium metal battery 210 consists essentially of lithium metal.

Alternatively, a separator may replace the solid state electrolyte 216, and the electrolyte for the lithium metal battery 210 may be a liquid electrolyte. An example separator material for the lithium metal battery 210 is one or more of the separator materials listed above for lithium ion battery 110. A suitable liquid electrolyte for the lithium metal battery 210 is one or more of the liquid electrolytes listed above for lithium ion battery 110.

The solid electrolyte interphases 217, 218 form during a first charge of the lithium metal battery 210. To further describe the formation of a solid electrolyte interphase, a non-limiting example lithium metal battery 210 using a liquid electrolyte and having a lithium metal anode is used in this paragraph. The liquid electrolyte comprises a lithium salt in an organic solvent. The non-limiting example lithium metal battery 210 is assembled in its discharged state which means with a lithium metal anode and lithiated positive cathode materials. The reduction potential of the organic solvent is typically below 1.0 V (vs. Li⁺/Li). Therefore, when the bare lithium anode is exposed to the electrolyte solution and a first charging current is applied, immediate reactions between lithium and electrolyte species are carried out. The insoluble products of the parasitic reactions between lithium ions, anions, and solvents depositing on the metallic lithium anode surface are regarded as the solid electrolyte interphase. As the SEI components strongly depend on the electrode material, electrolyte salts, solvents, as well as the working state of cell, no identical SEI layer can be found in two different situations. Consequently, the actual surface chemistry of SEI layer in a given system is typically obtained by characterization methods such as Fourier transform infrared spectroscopy (FTIR) and X-ray photoelectron spectroscopy (XPS).

The present invention is not limited to lithium metal batteries. In alternative embodiments, a suitable anode can comprise magnesium metal, sodium metal, or zinc metal. Suitable alternative cathode and electrolyte materials can be selected for such magnesium metal batteries, sodium metal batteries, or zinc metal batteries.

The present invention provides a method for manufacturing an electrochemical cell including an anode, an electrolyte, and a cathode including cations that move from the cathode to the anode during a charging phase of each of a plurality of cell cycles, wherein the cell undergoes degradation that results in loss of cation inventory during one or more charging phases of the cell cycles. The method comprises: (a) selecting at least one cell component selected from the group consisting of electrolyte materials, cathode active materials, and anode active materials, the at least one cell component causing the degradation of the cell; (b) selecting a formation protocol including: (i) a formation charging phase for creating a formed battery cell from a battery cell structure, and (ii) an aging phase for aging the formed battery cell; (c) calculating a solid electrolyte interphase (SEI) growth process based on the formation protocol and the at least one cell component using a solid electrolyte interphase growth model that predicts consumption of the cations and expansion of the cell; and (d) determining a property of the electrochemical cell based on the calculated solid electrolyte interphase growth process, wherein the property is selected from the group consisting of predicted end of life, capacity loss, resistance growth, gas generation, and electrode current collector dissolution.

In one embodiment of the method for manufacturing an electrochemical cell, the property is a predicted end of life. In one embodiment, the property is capacity loss. In one embodiment, the property is resistance growth. In one embodiment, the property is gas generation. In one embodiment, the property is electrode current collector dissolution.

In one embodiment of the method for manufacturing an electrochemical cell, the solid electrolyte interphase growth model includes an equation used for calculating boosted SEI growth dynamics during the formation charging phase. In one embodiment of the method for manufacturing an electrochemical cell, the solid electrolyte interphase growth model predicts solid electrolyte interphase film growth dynamics under multiple reacting species. In one embodiment of the method for manufacturing an electrochemical cell, the cell component is an electrolyte, and the solid electrolyte interphase growth model predicts consumption of a solvent of the electrolyte. In one embodiment of the method for manufacturing an electrochemical cell, the cell component is an electrolyte, and the solid electrolyte interphase growth model predicts consumption of an additive of the electrolyte. In one embodiment, the expansion of the cell includes reversible expansion from intercalation-induced electrode swelling and irreversible expansion from SEI growth. In one embodiment, the solid electrolyte interphase growth model predicts solid electrolyte interphase passivation properties. In one embodiment, the solid electrolyte interphase growth model predicts measured voltages. In one embodiment, the solid electrolyte interphase growth model predicts coulombic efficiencies. In one embodiment, the solid electrolyte interphase growth model predicts a dQ/dV curve during the formation charging phase. In one embodiment, the solid electrolyte interphase growth model predicts a first-cycle efficiency. In one embodiment, the solid electrolyte interphase growth model predicts cell thickness changes.

The present invention provides a method for monitoring real-time expansion of an electrochemical cell including an anode, an electrolyte, and a cathode including cations that move from the cathode to the anode during a charging phase of each of a plurality of cell cycles, wherein the cell undergoes degradation that results in loss of cation inventory during one or more charging phases of the cell cycles. The method comprises: (a) selecting at least one cell component selected from the group consisting of electrolyte materials, cathode active materials, and anode active materials, the at least one cell component causing the degradation of the cell; (b) calculating a solid electrolyte interphase (SEI) growth process based on the at least one cell component using a solid electrolyte interphase growth model that predicts consumption of the cations and expansion of the cell; and (c) determining real-time expansion of the electrochemical cell based on the calculated solid electrolyte interphase growth process.

In one embodiment of the method for monitoring real-time expansion of an electrochemical cell, step (a) further comprises selecting a formation protocol including: (i) a formation charging phase for creating a formed battery cell from a battery cell structure, and (ii) an aging phase for aging the formed battery cell, and step (b) further comprises calculating the solid electrolyte interphase (SEI) growth process based on the formation protocol. In one embodiment, the method comprises monitoring real-time expansion during the formation charging phase. In one embodiment, the method comprises monitoring real-time expansion during the aging phase.

In one embodiment of the method for monitoring real-time expansion of an electrochemical cell, step (b) further comprises calculating the solid electrolyte interphase growth process based on measurements of cell expansion. In one embodiment, the solid electrolyte interphase growth model includes an equation used for calculating boosted SEI growth dynamics during the formation charging phase. In one embodiment, the solid electrolyte interphase growth model predicts solid electrolyte interphase film growth dynamics under multiple reacting species. In one embodiment, the cell component is an electrolyte, and the solid electrolyte interphase growth model predicts consumption of a solvent of the electrolyte. In one embodiment, the cell component is an electrolyte, and the solid electrolyte interphase growth model predicts consumption of an additive of the electrolyte. In one embodiment, the expansion of the cell includes reversible expansion from intercalation-induced electrode swelling and irreversible expansion from SEI growth. In one embodiment, the solid electrolyte interphase growth model predicts solid electrolyte interphase passivation properties. In one embodiment, the solid electrolyte interphase growth model predicts measured voltages. In one embodiment, the solid electrolyte interphase growth model predicts coulombic efficiencies. In one embodiment, the solid electrolyte interphase growth model predicts a dQ/dV curve during the formation charging phase. In one embodiment, the solid electrolyte interphase growth model predicts a first-cycle efficiency. In one embodiment, the solid electrolyte interphase growth model predicts cell thickness changes.

The present invention provides a method for predicting a property of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolyte materials, cathode active materials, and anode active materials, the at least one cell component causing the degradation of the cell; (b) calculating a solid electrolyte interphase (SEI) growth process based on the at least one cell component using a solid electrolyte interphase growth model that predicts consumption of the cations and expansion of the cell; and (c) determining a property of the electrochemical cell based on the calculated solid electrolyte interphase growth process, wherein the property is selected from the group consisting of predicted end of life, capacity loss, resistance growth, gas generation, and electrode current collector dissolution.

In one embodiment of the method for predicting a property of an electrochemical cell, step (a) further comprises selecting a formation protocol including: (i) a formation charging phase for creating a formed battery cell from a battery cell structure, and (ii) an aging phase for aging the formed battery cell, and step (b) further comprises calculating the solid electrolyte interphase (SEI) growth process based on the formation protocol. In one embodiment, the method comprises monitoring real-time expansion during the formation charging phase. In one embodiment, the method comprises monitoring real-time expansion during the aging phase.

In one embodiment of the method for predicting a property of an electrochemical cell, step (b) further comprises calculating the solid electrolyte interphase growth process based on measurements of cell expansion. In one embodiment, the property is a predicted end of life. In one embodiment, the property is capacity loss. In one embodiment, the property is resistance growth. In one embodiment, the property is gas generation. In one embodiment, the property is electrode current collector dissolution. In one embodiment, the solid electrolyte interphase growth model includes an equation used for calculating boosted SEI growth dynamics during the formation charging phase. In one embodiment, the solid electrolyte interphase growth model predicts solid electrolyte interphase film growth dynamics under multiple reacting species. In one embodiment, the cell component is an electrolyte, and the solid electrolyte interphase growth model predicts consumption of a solvent of the electrolyte. In one embodiment, the cell component is an electrolyte, and the solid electrolyte interphase growth model predicts consumption of an additive of the electrolyte. In one embodiment, the expansion of the cell includes reversible expansion from intercalation-induced electrode swelling and irreversible expansion from SEI growth. In one embodiment, the solid electrolyte interphase growth model predicts solid electrolyte interphase passivation properties. In one embodiment, the solid electrolyte interphase growth model predicts measured voltages. In one embodiment, the solid electrolyte interphase growth model predicts coulombic efficiencies. In one embodiment, the solid electrolyte interphase growth model predicts a dQ/dV curve during the formation charging phase. In one embodiment, the solid electrolyte interphase growth model predicts a first-cycle efficiency. In one embodiment, the solid electrolyte interphase growth model predicts cell thickness changes.

The present invention provides a method in a data processing system comprising at least one processor and at least one memory, the at least one memory comprising instructions executed by the at least one processor to implement an electrochemical cell property prediction system, wherein the electrochemical cell includes an anode, an electrolyte, and a cathode including cations that move from the cathode to the anode during a charging phase of each of a plurality of cell cycles, wherein the cell undergoes degradation that results in loss of cation inventory during one or more charging phases of the cell cycles. The method comprises: (a) receiving a selection of at least one cell component selected from the group consisting of electrolyte materials, cathode active materials, and anode active materials, the at least one cell component causing the degradation of the cell; (b) calculating a solid electrolyte interphase (SEI) growth process based on the at least one cell component using a solid electrolyte interphase growth model that predicts consumption of the cations and expansion of the cell; and (c) determining a property of the electrochemical cell based on the calculated solid electrolyte interphase growth process.

In one embodiment of the method in a data processing system, step (a) further comprises selecting a formation protocol including: (i) a formation charging phase for creating a formed battery cell from a battery cell structure, and (ii) an aging phase for aging the formed battery cell, and step (b) further comprises calculating the solid electrolyte interphase (SEI) growth process based on the formation protocol. In one embodiment, the method comprises monitoring real-time expansion during the formation charging phase. In one embodiment, the method comprises monitoring real-time expansion during the aging phase.

In one embodiment of the method in a data processing system, step (b) further comprises calculating the solid electrolyte interphase growth process based on measurements of cell expansion. In one embodiment, the property is a predicted end of life. In one embodiment, the property is capacity loss. In one embodiment, the property is resistance growth. In one embodiment, the property is gas generation. In one embodiment, the property is electrode current collector dissolution. In one embodiment, the solid electrolyte interphase growth model includes an equation used for calculating boosted SEI growth dynamics during the formation charging phase. In one embodiment, the solid electrolyte interphase growth model predicts solid electrolyte interphase film growth dynamics under multiple reacting species.

In one embodiment of the method in a data processing system, the cell component is an electrolyte, and the solid electrolyte interphase growth model predicts consumption of a solvent of the electrolyte. In one embodiment of the method in a data processing system, the cell component is an electrolyte, and the solid electrolyte interphase growth model predicts consumption of an additive of the electrolyte. In one embodiment, the expansion of the cell includes reversible expansion from intercalation-induced electrode swelling and irreversible expansion from SEI growth. In one embodiment, the solid electrolyte interphase growth model predicts solid electrolyte interphase passivation properties. In one embodiment, the solid electrolyte interphase growth model predicts measured voltages. In one embodiment, the solid electrolyte interphase growth model predicts coulombic efficiencies. In one embodiment, the solid electrolyte interphase growth model predicts a dQ/dV curve during the formation charging phase. In one embodiment, the solid electrolyte interphase growth model predicts a first-cycle efficiency. In one embodiment, the solid electrolyte interphase growth model predicts cell thickness changes.

In any embodiments of the method for manufacturing an electrochemical cell, or the method for monitoring real-time expansion of an electrochemical cell, or the method for predicting a property of an electrochemical cell, or the method in a data processing system, the cations can be lithium cations.

In any embodiments of the method for manufacturing an electrochemical cell, or the method for monitoring real-time expansion of an electrochemical cell, or the method for predicting a property of an electrochemical cell, or the method in a data processing system, the anode can comprise an anode material selected from graphite, lithium titanium oxide, hard carbon, tin/cobalt alloys, silicon/carbon, or lithium metal, the electrolyte can comprise a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+Z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). In one embodiment, the electrolyte further comprises an electrolyte additive. In one embodiment, the electrolyte additive is selected from the group consisting of vinylene carbonate, fluoroethylene carbonate, and mixtures thereof. In one embodiment, the anode comprises graphite, the lithium compound is selected from LiPF₆, LiBF₄, LiClO₄, lithium bis(fluorosulfonyl)imide (LiFSI), LiN(CF₃SO₂)₂ (LiTFSI), and LiCF₃SO₃(LiTf), the organic solvent is selected from carbonate based solvents, ether based solvents, ionic liquids, and mixtures thereof, the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane, and mixtures thereof. In one embodiment, the anode comprises an anode material selected from sodium ions and sodium metal. In one embodiment, the anode comprises silicon.

### EXAMPLE

The following Example has been presented in order to further illustrate the invention and is not intended to limit the invention in any way. The statements provided in the Example are presented without being bound by theory.

### Overview of the Example

This Example provides a semi-empirical model for the SEI growth process during the early stages of lithium-ion battery formation cycling and aging. By combining a full-cell model that tracks half-cell equilibrium potentials, a zero-dimensional model of SEI growth kinetics, and a semi-empirical description of cell thickness expansion, the resulting model replicated experimental trends measured on a 2.5 Ah pouch cell, including the calculated first-cycle efficiency, measured cell thickness changes, and electrolyte reduction peaks during the first charge dQ/dV signal. This Example also introduces an SEI growth boosting formalism that enables a unified description of SEI growth during both cycling and aging. This feature can enable future applications for modeling path-dependent aging over a cell's life. The model further provides a homogenized representation of multiple SEI reactions enabling the study of both solvent and additive consumption during formation. This Example bridges the gap between electrochemical descriptions of SEI growth and applications towards improving industrial battery manufacturing process control where battery formation is an essential but time-consuming final step. We envision that the formation model can be used to predict the impact of formation protocols and electrolyte systems on SEI passivation and resulting battery lifetime.

### 1 Introduction

Every commercial lithium-ion battery undergoes formation cycling and aging at the end of the battery cell manufacturing process [Ref. 1,2]. The formation process is time and capital-intensive, motivating battery manufacturers to develop new formation protocols to decrease formation time while maintaining battery lifetime and safety [Ref. 2]. Yet, despite the importance of battery formation, a general framework for modeling the formation process for commercial lithium-ion battery systems is lacking. Without these models, formation protocol optimization will require brute-force, trial-and-error approaches, which are slow, inefficient, and not guaranteed to yield optimal outcomes.

The main goal of battery formation is to form a passivating solid electrolyte interphase (SEI) layer at the negative electrode surface which limits further SEI growth over the battery's life [Ref. 3-6]. SEI growth occurs throughout the battery formation process which consists of both cycling and calendar aging steps. During formation cycling, the battery is externally charged and discharged for the first time following electrolyte filling [Ref. 2]. Formation cycling is followed by formation aging, during which the battery cells are stored at high temperatures and high states of charge (SOCs) for days to weeks to continue the SEI growth process and screen for quality defects [Ref. 2].

The SEI reaction and film growth process is complex. Multiple reaction pathways are often involved since multiple electrolyte components, including solvents and additives, can participate simultaneously in the SEI reaction [Ref. 1, Ref. 5, Ref. 7]. The resulting SEI film is thus heterogeneous in composition [Ref. 5, Ref. 8, Ref. 9]. The SEI film is also difficult to study experimentally owing to the reactivity of the electrode-electrolyte interface and the nanometer thickness of the film [Ref. 1, Ref. 5]. These inherent complexities of the SEI growth process partly explain why existing SEI growth models are difficult to parameterize and experimentally validate, hindering their applications in a battery manufacturing context for formation process design and lifetime prediction.

### 1.1 A Phenomenological Basis for Formation Modeling

Despite the microscopic complexities of SEI growth, the battery formation process for commercial-scale cells yields electrochemical signals which can be directly measured using standard equipment during formation cycling. FIG. 1B shows example data collected on a 2.5 Ah pouch cell (Panel B) that underwent three formation charge-discharge cycles, followed by reference performance tests (RPTs), followed by formation aging (see Section 2.1 for more experimental details). This dataset can be directly used to calculate the coulombic efficiency (CE), according to:

$$\\ \begin{matrix}{CE}_{i} = \frac{{Q}_{d , i}}{{Q}_{c , i}} , & ( 1 )\end{matrix}$$

where Q_{d,i} and Q_{c,i} are the discharge and charge capacities of the ith cycle, calculated via current integration. The CE of the first cycle, also known as the first cycle efficiency (FCE), is characteristically lower than the CE for all subsequent cycles owing to the rapid consumption of lithium during the first charge cycle to form the SEI.

For pouch cell form factors, thickness expansion can also be directly measured using a sensor fixture shown in FIG. 1B, Panel C [Ref. 10, Ref. 11, Ref. 12]. The measurements suggest that total cell expansion can be attributed to two distinct sources. The first source is due to changes in the lithium content (or stoichiometry) in the positive and negative electrode particles. During lithiation, the particles swell, and during delithiation, the particles contract. Since this process is reversible, we will refer to this source as “reversible expansion.” The reversible expansion tracks closely to the measured cell voltage, or state of charge (SOC), which determines the lithium content in either electrode. The second source of expansion can be noticed from the minimum expansion at the end of every discharge cycle. This expansion appears to always increase over cycles. We will thus refer to this expansion source as “irreversible expansion” [Ref. 11, Ref. 13]. The irreversible expansion is attributed to the growth of the SEI layer during formation and aging. Consistent with the CE data, the irreversible expansion is high during the first cycle, but then slows down over the next two cycles. During formation aging, the irreversible expansion rate appears to decrease, indicating a possibly slower SEI growth process compared to cycling.

### 1.2 Contributions

This Example presents a semi-empirical modeling framework describing the SEI growth process during battery formation cycling and aging. The model builds on established electrochemical descriptions of SEI growth which uses Butler-Volmer kinetics to describe the SEI-forming solvent reduction process [Ref. 14-17] and linearized Fick's law to describe solvent diffusion [Ref. 4, Ref. 18-20]. To model cell expansion, a semi-empirical approach is taken which draws from existing literature [Ref. 10, 21-25], but separates the reversible and irreversible expansion contributions to the total expansion. Since our aim is to develop a reduced-order description of SEI growth which can be deployed in a battery manufacturing context, our modeling approach does not explicitly consider spatial variations in the SEI layer [Ref. 26-29] or competing reaction pathways [Ref. 8]. However, as will be demonstrated, a reduced-order, zero-dimensional model can accurately capture macroscopic, observed trends during both formation cycling and aging shown in FIG. 1B, including CE, expansion, and first cycle dQ/dV peaks indicating electrolyte reduction processes.

Our model introduces three extensions to the existing literature on zero-dimensional SEI growth models. First, we introduce a semi-empirical model of macroscopic thickness expansion of the battery, accounting for both the reversible expansion due to lithium intercalation reactions as well as the irreversible expansion due to SEI growth (see Section 3.6). Second, we introduce a mathematical formalism to describe “boosted SEI growth” during charging (see Section 3.7). This model extension unifies the description of SEI growth and cell expansion during cycling, which is fast, and during calendar aging, which is slow. Finally, we introduce a homogenized, multi-species representation of the SEI growth process, enabling the prediction of volume-averaged SEI film properties under multiple reacting species (see Section 3.8). This model extension enables a description of solvent consumption and additive consumption as two parallel and coupled processes which combine to create a composite SEI film with a volume-averaged film diffusivity.

The formation model we develop resolves the dynamics of lithium consumption and cell expansion during formation cycling and aging. The same model can be applied to track lithium inventory loss over the remaining life of the cell, including during cyclic aging and calendar aging. By explicitly considering multiple electrolyte reduction reactions during the first cycle, the model also provides a pathway for future studies on how formation protocols influence SEI passivation properties [Ref. 30] and their consequences on battery lifetime.

### 2 Experimental Methods

FIG. 1B summarizes the experimental data collected for this Example. This dataset defines a basic set of macroscopic observations that the formation model will seek to capture. The experiment consists of three parts: (1) formation cycling, (2) reference performance testing (RPTs), and (3) formation aging at 100% state of charge (SOC). The proceeding sections describe the cell build process in relation to the formation cycling and aging experiments shown in FIG. 1B, Panel A.

### 2.1 Cell Build

Experimental data was collected on a 2.5 Ah, multi-layer stacked pouch cell (FIG. 1B, Panel B). The cell was built on a prototype cell manufacturing line using a process similar to the one outlined in Weng et al. [Ref. 31]. The cell included a single-crystal Ni_{0.6} Mn_{0.2} Co_{0.2} (NMC622) positive electrode (Targray) and a graphite negative electrode (Superior SLC, 1520-T), based on the available stock. A standard electrolyte formulation was used (SoulBrain PuriEL R&D 326), which consisted of ethylene carbonate (EC) and ethyl methyl carbonate (EMC) in a 3:7 weight ratio, 1.0 M LiPF₆ and 2 wt % vinylene carbonate (VC) additive. The cell stack consisted of 7 double-sided positive electrode layers and 8 double-sided negative electrode layers, resulting in 14 active unit cells along the pouch cell thickness direction. The positive electrode formulation consisted of NMC622:C65:PVDF (94:3:3), where C65 and PVDF are binder materials. The negative electrode consisted of graphite: CMC:SBR (97:1.5:1.5), where CMC and SBR are binder materials. Positive (negative) electrode single-sided loadings were 17.2 (9.7) mg/cm² and with porosity targets of 30% (20%). The negative-to-positive capacity ratio was targeted to be 1.1.

### 2.2 Electrolyte Filling and Cell Fixture

After electrolyte filling and enclosure sealing, cells were loaded in a custom-built pressure fixture shown in FIG. 1B, Panel C. The pressure fixture was developed based on work by Mohtat et al. [Ref. 10]. The fixture applied 5 psi of compression via a spring-loaded plate. To minimize copper dissolution at high negative electrode potentials immediately after electrolyte filling [Ref. 32], the cell was tap charged to 2.8V at a C/3 charge rate. The cell was subsequently left overnight to ensure the electrodes were completely wetted before formation charging.

### 2.3 Formation Cycling and Aging

Formation cycling was conducted while the cell/fixture assembly was placed in a temperature-controlled oven set to 45° C. The fixture maintained a pressure of 5 psi throughout formation cycling and aging. For formation cycling, the cell was charged and discharged using an Arbin BT2000 system.

The formation protocol consisted of three back-to-back charge-discharge cycles at a rate of C/10. Each charge terminated when the cell reached 4.2V, followed by a CV hold step with a C/20 current cut-off. Each discharge terminated when the cell reached 3.0V without CV holding. No rest periods were included between each charge and discharge.

Formation cycling was followed by a reference performance test (RPT), which included a pulse charge-discharge sequence for calculating cell resistances and C/20 charge-discharge voltage curves for dV/dQ analysis [Ref. 31]. The details and contents of the RPT are not immediately relevant to this Example, but the RPT data has been presented here to preserve data continuity with the subsequent experimental step.

After the RPT, the cell was charged to 100% SOC to undergo formation aging at 45° C. The goal of this step was to ensure SEI passivation and to screen for quality defects [Ref. 2]. This aging step lasted for 14 days. After aging, the cell was finally discharged. Note that FIG. 1B, Panel A only shows the first 10 days of the 14-day aging protocol for brevity.

### 2.4 Expansion Measurements

Thickness expansion of the cell was measured using a linear displacement sensor (Keyence GT2 series) mounted to the fixture (FIG. 1B, Panel C). Expansion data was logged in real-time using a data acquisition system (LabVIEW) throughout the entire experiment. The expansion data was combined with the electrical signals during post-processing.

### 3 Model Formulation

### 3.1 Model Assumptions

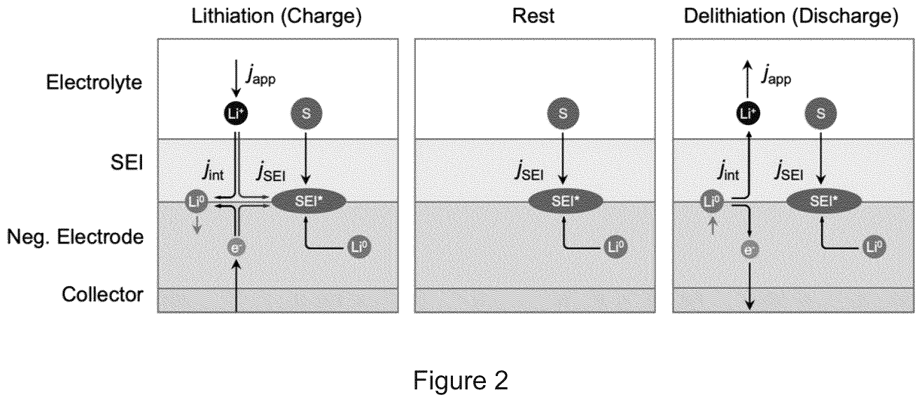

FIG. 2 shows the canonical reaction pathways for SEI formation [Ref. 4, Ref. 33] assumed for this Example. The general SEI reaction is represented by:

$$\\ \begin{matrix}n {Li}^{{}_{} +} + {ne}^{{}_{} -} + S \to SEI ↓ + {}_{} P ↑ , & ( 2 )\end{matrix}$$

where S represents a solvent molecule, n is the number of participating electrons, ‘SEI’ stands for the newly-formed solid reduction product, and P denotes some reaction byproduct, usually a gas [Ref. 34]. Candidate solvent molecules include ethylene carbonate (EC) and diethyl carbonate (DEC). Note that S can also represent electrolyte additives such as vinylene carbonate (VC).

To build a model of SEI growth during both formation cycling and aging, SEI reaction pathways occurring during full cell charging, discharging, and rest, need to be consolidated. Doing so enables the same modeling framework to simulate both cycling and calendar aging after formation completes. The reaction formulation we chose, summarized by Attia et al. [Ref. 33], considers two distinct SEI reaction modes, termed ‘electrochemical’ SEI growth, which occurs in the presence of external current (i.e. during charge and discharge), and ‘chemical’ SEI growth, which always occurs. Both SEI growth mechanisms share the same general reaction scheme described by Eq. 2, but only differ by the source of lithium. In ‘electrochemical’ SEI growth, the external current drives solvated lithium ions from the electrolyte towards the reaction interface. In ‘chemical’ SEI growth, intercalated lithium from the negative electrode migrates to the reaction interface. These reaction modes will be unified by the model formulation presented in Section 3.4.

Further general modeling assumptions are listed below:
Reaction interface. The SEI-forming reaction takes place exclusively at the electrode-SEI interphase [Ref. 4].
Rate-limiting mechanisms. The SEI reaction rate is determined by two processes: (1) interfacial reaction kinetics according to Butler-Volmer kinetics, and (2) diffusion-limited solvent transport through a porous SEI. No other rate-limiting mechanisms such as electron conduction [Ref. 27] are considered.
Idealized degradation. SEI reaction at the negative electrode is the only source of full cell capacity loss. Considerations for other degradation modes, such as thermal SEI decomposition [Ref. 33], lithium plating [Ref. 35], active material degradation (e.g. cathode phase transformations [Ref. 36], particle cracking [Ref. 37], binder delamination [Ref. 39]), and positive electrode side-reactions [Ref. 39, Ref. 40], are left for future work.
Irreversibility. SEI reactions are irreversible.
No gas formation. Gas-forming reaction dynamics [Ref. 34] are ignored and left for future work.
No cross-talk. Cross-reactions between different electrolyte components are left as future model extensions.

### 3.2 Electrode Potentials and Solid-Phase Lithium Stoichiometries

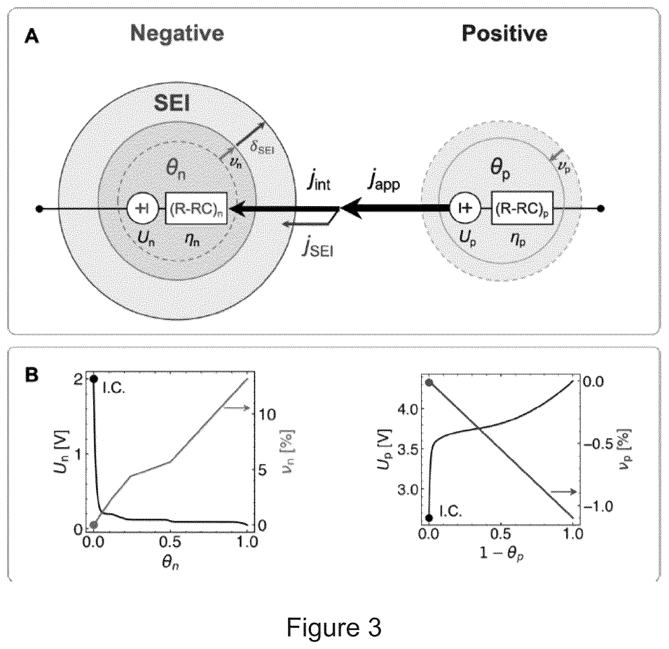

A reduced-order full-cell model was used as a starting point for this Example, shown in FIG. 3. In this model, the negative electrode equilibrium surface potential, Uₙ, provides the thermodynamic basis for SEI-forming reactions. However, Uₙ is not directly controllable or observable during the formation process in commercial devices. Rather, the terminal voltage, Vₜ, is observed and controlled. A practical model of battery formation therefore requires a description of Vₜ, written as:

$$\\ \begin{matrix}{V}_{t} = {U}_{p} ( {θ}_{p}^{{}_{} s} ) - {U}_{n} ( {θ}_{n}^{{}_{} s} ) + {η}_{p} + {η}_{n} , & ( 3 )\end{matrix}$$

where Uₚ is the positive electrode equilibrium surface potential, θₚ^{s} and θₙ^{s} are the lithium stoichiometries at the electrode surfaces, and ηₚ and ηₙ are electrode overpotentials. Uₙ and Uₚ are described by empirical functions such as the ones shown in FIG. 3, Panel B. The lithium stoichiometries are defined by:

$$\\ \begin{matrix}{θ}_{p}^{{}_{} s} = {c}_{s , p}^{{}_{} s} / {c}_{s , p}^{{}_{} max} & ( 4 )\end{matrix}$$

$$\\ \begin{matrix}{θ}_{n}^{{}_{} s} = {c}_{s , n}^{{}_{} s} / {c}_{s , n}^{{}_{} max} , & ( 5 )\end{matrix}$$

where c_{s,p}^{s} (c_{s,n}^{s}) is the lithium concentration at the surface of the positive (negative) electrode, and c_{s,p}^{max}(c_{s,n}^{max}) is the maximum lithium concentration of the positive (negative) electrode. Finding the lithium surface concentrations will typically require solving the spherical diffusion equation [Ref. 41]. Here, we simplify the representation by assuming that the current density is sufficiently low such that the solid-phase concentration gradient is approximately zero, hence c_{s,i}^{s}≈c_{s,i}^{avg}. Hence, the lithium stoichiometries can be directly updated via Coulomb counting the intercalation current:

$$\\ \begin{matrix}\frac{d {θ}_{p} ( t )}{dt} = - \frac{{I}_{app} ( t )}{{Q}_{p}} & ( 6 )\end{matrix}$$

$$\\ \begin{matrix}\frac{d {θ}_{n} ( t )}{dt} = + \frac{{I}_{int} ( t )}{{Q}_{n}} , & ( 7 )\end{matrix}$$

where θₚ and θₙ are the average lithium stoichiometries, Qₚ and Qₙ are the total electrode capacities corresponding to c_{s,p}^{max} and c_{s,n}^{max}, respectively, Iₐₚₚ is the applied current into the full cell, and Iᵢₙₜ is the intercalation current at the negative electrode. We take the convention that Iₐₚₚ>0 when the cell is charged. Similarly, Iᵢₙₜ>0 corresponds to lithium intercalation into the negative electrode. At the positive electrode, the intercalation current and the applied current are equal since our model assumed no side reactions at the positive electrode. At the negative electrode, the applied current is split between the intercalation current and the SEI reaction current, and only the intercalation current contributes to updating the lithium stoichiometry in the negative electrode. Overall, Eqs. 6 and 7 amount to a zero-dimensional, ‘dual-tank’ representation of lithium stoichiometries at each electrode, providing a basis for tracking reaction potentials and expansions at each electrode (FIG. 3, Panel B).

### 3.3 Electrode Overpotentials

The electrode surface overpotentials are governed by charge-transfer kinetics at the electrode-electrolyte interface and solid-state diffusion dynamics. Our Example reduces the overpotential dynamics using a first-order representation as follows:

$$\\ \begin{matrix}{η}_{i} ( t ) = {R}_{ct , i} {I}_{app} ( t ) + {R}_{diff , i} {I}_{diff , i} ( t ) , & ( 8 )\end{matrix}$$

where i is an index for the positive (p) or negative (n) electrode, ηᵢ is the overpotential, R_{ct,i} is a lumped resistance term that includes both series and charge-transfer resistance, R_{diff,i} represents solid-state diffusion resistance, and I_{diff,i} follows first-order dynamics given by [Ref. 42]:

$$\\ \begin{matrix}\frac{{dI}_{diff , i} ( t )}{dt} = - \frac{1}{{τ}_{diff , i}} {I}_{diff , i} ( t ) + \frac{1}{{τ}_{diff , i}} {I}_{app} ( t ) , & ( 9 )\end{matrix}$$

where τ_{diff,i} is the diffusion time constant. Note that Eqs. 8 and 9 are identical to the equations for an R-RC equivalent circuit model.

The negative electrode reaction potential, ηₙ, will play a role in determining the SEI reaction kinetics at the negative electrode-electrolyte interphase, which will be detailed in the next section.

### 3.4 SEI Reaction Kinetics

Since our experimental data uses ethylene carbonate (EC) as a solvent, we will describe our representation of SEI reaction kinetics in the context of EC reduction for convenience. However, it is to be understood that the formulation described here can apply to any SEI reaction that follows Eq. 2. A canonical EC reduction reaction pathway proceeds according to [Ref. 43, Ref. 44]:

$$\\ \begin{matrix}2 EC + 2 {e}^{{}_{} -} + 2 {Li}^{{}_{} +} \to LEDC ↓ {}_{} + {C}_{2} {H}_{4} ↑ , & ( 10 )\end{matrix}$$

where LEDC is lithium ethylene dicarbonate, the solid reaction product considered to be the SEI [Ref. 45], and C₂H₄ is ethylene gas. The SEI reaction current density is assumed to take a Tafel-like form [Ref. 16]:

$$\\ \begin{matrix}{j}_{SEI} = {nFk}_{SEI} {c}_{EC}^{{}_{} s} exp ( - \frac{{α}_{SEI} nF}{RT} {η}_{SEI} ) , & ( 11 )\end{matrix}$$

where k_{SEI} is the reaction rate constant, c_{EC}^{s} is the concentration of solvent molecules at the reaction surface, α_{SEI} is the symmetry factor, and η_{SEI} is the SEI reaction overpotential. n is the number of electrons involved in the reaction. For the EC reaction, n=2. In the Doyle-Fuller-Newman model, nSEI is determined by [Ref. 46, Ref. 47]:

$$\\ \begin{matrix}{η}_{SEI} = {ϕ}_{s , n} - {ϕ}_{e} - {U}_{SEI} - {j}_{app} {R}_{SEI} {δ}_{SEI} , & ( 12 )\end{matrix}$$

where ϕ_{s,n} is the electrode surface potential, ϕₑ is the electrolyte potential, U_{SEI} is the SEI reaction potential, R_{SEI} is the SEI resistivity, and δ_{SEI} is the SEI thickness. Note that ϕ_{s,n} and ϕₑ do not explicitly appear in our formulation due to our simplified model representation. To then define ηₙ in our system, we notice that [Ref. 46, Ref. 47]:

$${η}_{n} = {ϕ}_{s , n} - {ϕ}_{e} - {U}_{n} ( {θ}_{n}^{s} ) - {j}_{a p p} {R}_{SEI} {δ}_{SEI} , \qquad ( 13 )$$

which can be substituted into Eq. 12 to yield:

$${η}_{SEI} = {η}_{n} + {U}_{n} ( {θ}_{n}^{s} ) - {U}_{S E I} . \qquad ( 14 )$$

Eq. 14 is now directly solvable, since ηₙ is provided for by Eq. 8. Note that this representation of η_{SEI} does not explicitly represent the SEI resistivity R_{SEI}. However, this is easily remedied by lumping R_{SEI} into R_{ct,n} in Eq. 8.

Solvent transport limitations through the SEI is modeled using a linearized Fick's law which takes the form [Ref. 47, Ref. 48]:

$${D}_{S E I} \frac{{c}_{EC}^{s} - {c}_{E C}^{0}}{{δ}_{SEI}} = \frac{{j}_{SEI}}{n F} , \qquad ( 15 )$$

where D_{SEI} is the effective diffusivity of the SEI and c_{EC}⁰ is the concentration of solvent molecules in the bulk electrolyte phase. Reniers et al. combined Eqs. 11 and 15 into a more explicit representation of the reaction and diffusion-limited processes by eliminating c_{EC}^{s} from the equations, yielding [Ref. 19, Ref. 49]:

$${j}_{SEI} = \frac{- {c}_{EC}^{0}}{1 / ( n {Fk}_{S E I} exp ( - {α}_{S E I} n F {η}_{SEI} / RT ) ) + {δ}_{S E I} / ( {D}_{S E I} n F )} . \qquad ( 16 )$$

We further rewrite Eq. 16 in terms of two limiting currents:

$$\frac{1}{{j}_{SEI}} = \frac{1}{{\tilde{J}}_{SEI , rxn}} + \frac{1}{{\tilde{J}}_{SEI , dif}} , \qquad ( 17 )$$

$$with :$$

$${\tilde{J}}_{SEI , rxn} {=}^{Δ} n {Fk}_{S E I} {c}_{EC}^{0} exp ( - \frac{{α}_{SEI} n F}{RT} {η}_{SEI} ) \qquad ( 18 )$$

$${\tilde{J}}_{SEI , dif} {=}^{Δ} \frac{n {FD}_{S E I} {c}_{EC}^{0}}{{δ}_{S E I}} . \qquad ( 19 )$$

Eq. 18 represents the reaction-limited SEI current in the absence of diffusion limitations (c_{EC}^{s}=c_{EC}⁰) while Eq 19 represents the diffusion-limited SEI current in the absence of reaction limitations (c_{EC}^{s}=0). Eq. 17 thus highlights that the SEI current is the harmonic mean of two limiting currents. The slower of the two processes limits the overall flow of SEI current.

The SEI current density can be converted to total SEI current by:

$${I}_{S E I} = {a}_{s , n} {A}_{n} {L}_{n} {j}_{SEI} , \qquad ( 20 )$$

where a_{s,n} is the specific surface area (i.e. surface-to-area volume ratio) of the negative electrode, Aₙ is the geometric area of the negative electrode, and Lₙ is the geometric thickness of the negative electrode. The SEI current can then be directly integrated to yield the total capacity of lithium lost to SEI-forming reactions:

$${Q}_{SEI} = \int {I}_{S E I} ( t ) dt . \qquad ( 21 )$$

Current conservation can finally be used to solve for the total lithium intercalation current:

$${I}_{i n t} = {I}_{a p p} - {I}_{S E I} . \qquad ( 22 )$$

Eq 22 unifies the SEI reactions during charging, discharging, and resting, according to the reaction scheme proposed in FIG. 2. During charging, Iₐₚₚ is positive and is split between Iᵢₙₜ and I_{SEI} which are both positive. During discharging, Iₐₚₚ and Iᵢₙₜ are both negative, but I_{SEI} remains positive since the SEI reaction is irreversible. During rest, Iₐₚₚ=0 so Iᵢₙₜ=−I_{SEI}, consistent with the scheme that lithium deintercalation from the negative electrode drives the SEI reaction during rest. In all cases, Eqs. 17 and 22 provide a consistent framework for capture the SEI reaction dynamics.

### 3.5 Solvent Consumption

As SEI grows, solvent molecules are consumed according to Eq. 2,decreasing the bulk solvent concentration. The solvent consumption process can be described by:

$$\frac{d {c}_{E C}^{0}}{dt} = \frac{{a}_{s , n} {j}_{S E I}}{n F} . \qquad ( 23 )$$

As solvent is consumed, j_{SEI} is further decreased according to Eq. 16. The solvent depletion process is thus self-limiting.

### 3.6 Expansion Modeling

The goals of developing an expansion model are three-fold. First, an expansion model enables the prediction of macroscopic expansion trends during formation cycling and aging seen in FIG. 1B, which could then be extended to predict expansion over the remaining lifetime of the cell. Second, the predicted expansion dynamics can lead to deeper insights into the formation process since SEI growth and irreversible cell expansion are linked. Finally, an expansion model fit to experimental expansion data enables a richer dataset for model parameterization.

This Example proposes a phenomenological representation of the total cell thickness expansion, Δₜₒₜ, of the form:

$${Δ}_{t o t} ( t ) = {Δ}_{S E I} ( t ) + {Δ}_{rev} ( t ) . \qquad ( 24 )$$

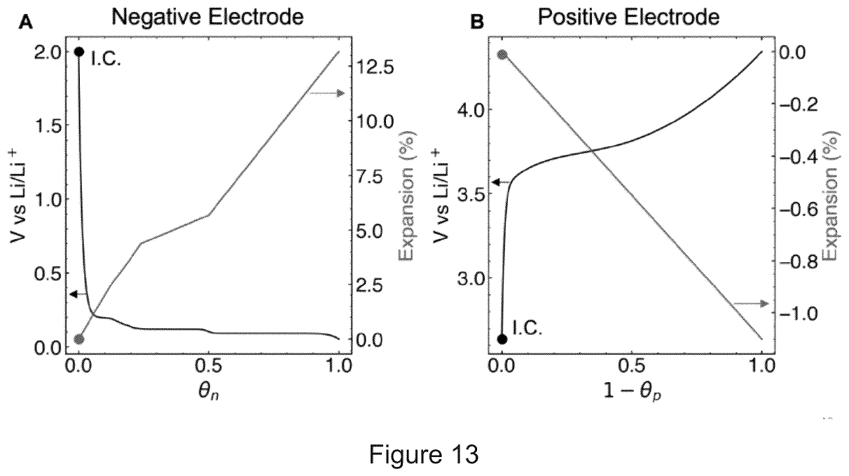

The first term in Eq. 24 represents the irreversible cell thickness expansion due to SEI film growth and is given by:

$${Δ}_{S E I} ( t ) = \frac{{N}_{layers} {L}_{n}}{{R}_{n} ( 1 + {v}_{n} ( {θ}_{n} ( t ) ) / 3 )} {δ}_{S E I} ( t ) , \qquad ( 25 )$$

where δ_{SEI} is SEI film thickness at a negative electrode particle, Lₙ is the geometric length of the negative electrode, and N_{layers} is the number of active layers in the stacked configuration. Rₙ is the radius of a single negative electrode particle and vₙ is the reversible expansion function of the negative electrode (see FIG. 13). Eq. 25 is derived in Section 10.

The SEI film thickness, δ_{SEI}, evolves due to the accumulation of SEI current according to Safari et al. [Ref. 16]:

$$\frac{d {δ}_{S E I}}{dt} = {V}_{m , S E I} \frac{{j}_{SEI}}{n F} . \qquad ( 26 )$$

V_{m,SEI} is the SEI molar volume in m³/mol, defined by

$${V}_{m , S E I} {=}^{Δ} {M}_{S E I} / {ρ}_{S E I} ,$$

where M_{SEI} is the SEI molecular weight and ρ_{SEI} is the SEI density.

The second term in Eq. 24 represents the reversible expansion of the positive and negative electrodes, given by:

$${Δ}_{rev} ( t ) = {N}_{layers} \cdot ( \frac{{L}_{p}}{3} {v}_{p} ( {θ}_{p} ( t ) ) + \frac{{L}_{n}}{3} {v}_{n} ( {θ}_{n} ( t ) ) ) , \qquad ( 27 )$$

where vₚ and vₙ are the volumetric expansion functions for each electrode, shown in FIGS. 3 and 13. The reversible volumetric expansion functions are due to lithium intercalation-induced swelling of the electrodes. Graphite, for example, expands up to 12% volumetrically during lithiation [Ref. 50]. Layered oxide materials also expand and contract, but the total expansion depends on the range of lithium stoichiometries reachable within the full cell voltage window [Ref. 51]. The expansion functions vₚ and vₙ are typically quantified by measuring unit cell lattice parameter changes during lithiation and delithiation via in-situ X-ray diffraction [Ref. 50, Ref. 51]. The prefactor terms convert the microscopic volumetric expansions to macroscopic thickness expansions and are derived in Section 10.

Further expansion modeling assumptions and clarifications are given as follows:
Expansion and compression of the inactive layers, including the separators, current collectors, and pouch cell enclosure, are ignored.
Electrode particles are spherical.
The expansion functions vₚ(θₚ) and vₙ(θₙ) remain invariant over the formation and aging process.
Expansion and contraction in the electrode planar direction are ignored.

### 3.7 Boosted SEI Growth Rate During Charging

Here, we introduce a concept called “SEI growth boosting”. The boosting refers to enhanced SEI growth rate during cell charging which has been previously explored in the context of degradation modeling [Ref. 21, Ref. 22, Ref. 52]. This effect is especially important to consider during formation cycling, during which the electrodes are experiencing the largest change in lithium stoichiometry. This stoichiometry change creates more particle-level strains which exposes new reaction surfaces, boosting the SEI growth rate [Ref. 22, Ref. 52]. As we will later show in Section 5.3, this model extension was necessary for unifying the observed macroscopic formation trends during both formation cycling and formation aging as shown in FIG. 1B.

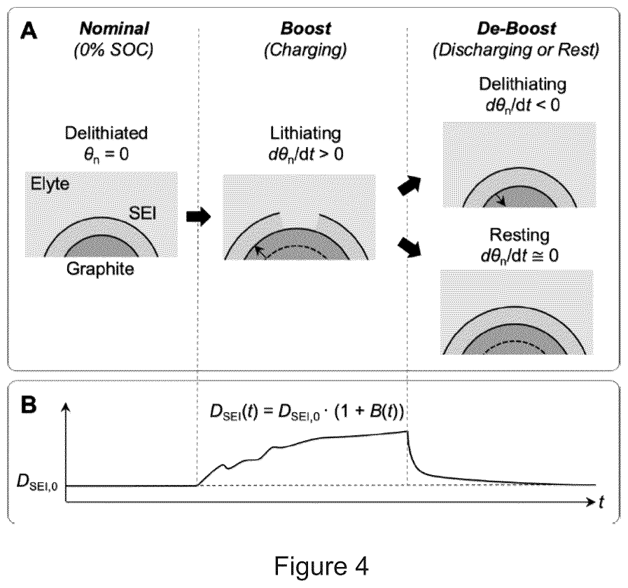

FIG. 4 illustrates the boosted SEI growth mechanism. Panel A describes a graphite particle that starts at some initial state of lithiation θₙ=θ_{n,0}. As the full cell is charged, the graphite lithiates and expands. Ideally, the SEI elastically deforms to accommodate the particle swelling. However, if the SEI film is brittle, then parts of the SEI film may fracture, exposing fresh electrode surfaces to new electrolyte [Ref. 22], shown in FIG. 4, Panel A. Reacting molecules near these newly-exposed electrode surfaces will see more facile reaction kinetics since no pre-existing SEI film is present to limit the diffusion of reacting molecules to the reaction surface. The overall SEI current density will thus be temporarily boosted.

Next, we consider the case of delithiation and resting. During resting, new SEI is formed to fill in the fresh electrode surfaces. As the SEI thickness in these regions approach the volume-averaged thickness, the overall SEI reaction rate is restored to the rate prior to boosting. During delithiation, the SEI is assumed to remain in contact with the graphite particles which are contracting, so no new electrode surfaces are exposed. Note that this assumption may be violated by systems having high volumetric expansions such as silicon [Ref. 53] which we leave for future work to explore. Overall, during resting and discharging, we assume that boosting no longer occurs and the SEI growth rate is gradually restored to the original rate prior to boosting.

This Example interprets the SEI growth boosting process as a modification to the effective SEI diffusivity, D_{SEI}. In this interpretation, newly exposed electrode surfaces are represented as increases to the local SEI porosity which in turn increase the volume-averaged SEI porosity ε. Changes in the volume-averaged porosity are represented by the effective diffusivity according to [Ref. 54, Ref. 55]:

$${D}_{S E I} ( t ) = {D}_{SEI , 0} \frac{ε ( t )}{τ} , \qquad ( 28 )$$

where D_{SEI} is the effective diffusivity that we have been using for this Example, D_{SEI,0} is a reference diffusivity, ε is the volume-averaged SEI film porosity, and τ is the tortuosity. Note that this expression can be further simplified using the Bruggeman relation τ=ε^{-0.5 [}Ref. 46].

To describe the dynamics of the porosity evolution, we define an empirical “boost factor” B(t) which modifies the effective SEI diffusivity according to:

$${D}_{S E I , b o o s t e d} ( t ) = {D}_{SEI , 0} ( 1 + B ( t ) ) , \qquad ( 29 )$$

where D_{SEI,boosted} is the boosted SEI diffusivity. We assume that the dynamics of boosting is described by some unknown function f(B(t)) which is driven by the negative electrode expansion rate:

$$f ( B ( t ) ) = γ \frac{d {v}_{n} ( {θ}_{n} )}{dt} , \qquad ( 30 )$$

where vₙ is the negative electrode volume expansion function and γ is an input sensitivity parameter. A first-order Taylor expansion of f(B(t)) leads to our proposed state equation describing SEI growth boosting:

$$τ \frac{d B}{dt} + B = γ \frac{d {v}_{n}}{dt} . \qquad ( 31 )$$

In this equation, τ is the time constant for the first-order dynamics. This equation can be further separated for boosting during lithiation and “de-boosting” during delithiation and rest, with separate time constants describing each process:

$$\{ \begin{matrix}{τ}_{↑} \frac{d B}{dt} + B & = γ \frac{d {v}_{n}}{dt} & {I}_{a p p} > 0 & ( Boost ) \\ {τ}_{↓} \frac{d B}{dt} + B & = 0 & {I}_{a p p} \leq 0 & ( De - boost ) .\end{matrix} \qquad ( 32 )$$

During charging, the boosting time constant τ_{↑} describes how quickly the effective diffusivity increases in response to newly-created reaction surfaces for SEI growth. During discharging and resting, the de-boosting time constant τ_{↓} describes the rate of “self-healing” as the freshly-created surfaces fill up with new SEI and the effective diffusivity approaches its original value, D_{SEI,0}.

### 3.8 Homogenized Multi-Species SEI Reaction Model

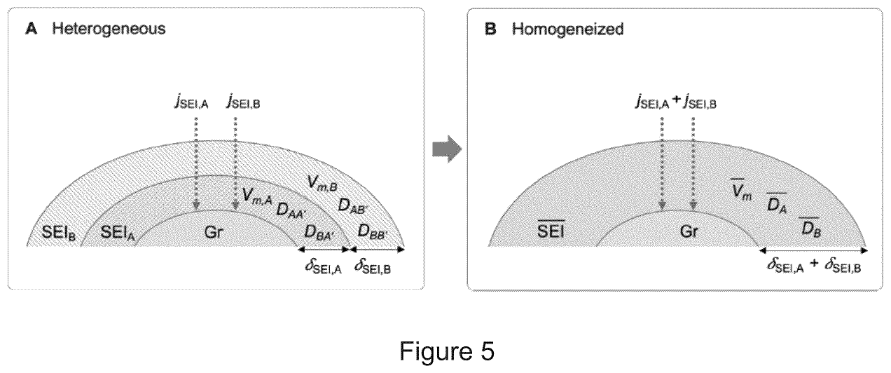

So far, our description of SEI growth reaction kinetics applied to the case of a single reacting species to form a single-component SEI solid product. However, the SEI growth process in commercially-relevant systems involves the simultaneous reaction of multiple electrolyte components including solvent and additive components. We therefore extend our model to describe the case of multiple reacting species, using FIG. 5 as a guide. This model extension enables a reduced-order representation of multiple, parallel SEI reactions. We will later demonstrate the usage of this model to represent the reaction of two electrolyte components, a solvent species (EC) as well as an additive species (VC), during the first formation charge cycle (see Section 5.1).

This model extension treats each SEI reaction as being governed by its own set of rate parameters (e.g. U_{SEI}, D_{SEI}, k_{SEI}, . . . ). However, the reactions kinetics become coupled since all reacting species must diffuse through the same set of solid SEI products to reach the reaction interface. Moreover, at the reaction interface, the charge-transfer reaction kinetics also become coupled since the chemical state of the electrode is described by Uₙ, a singule value that evolves as a function of the total integrated SEI reaction current. A mathematical treatment is as follows.

Each SEI reaction proceeds according to Eq. 2 and is assumed to occur in parallel. The total SEI reaction current density thus takes the form:

$${j}_{SEI} = {\sum }_{r} {j}_{SEI , r} \qquad ( 33 )$$

$$= {\sum }_{r} {( \frac{1}{{\tilde{J}}_{SEI , rxn , r}} + \frac{1}{{\tilde{J}}_{SEI , dif , r}} )}^{- 1} , \qquad ( 34 )$$

where r={EC, VC, . . . } represents the different electrolyte species that are reduced to form their respective SEI solid products, and the expansion of the right-hand side is due to Eq. 17.

The reaction-limited current density for the rth species is:

$${\tilde{J}}_{SEI , rxn , r} = {n}_{r} F {k}_{SEI , r} {c}_{S E I , r}^{0} exp ( - \frac{{α}_{SEI , r} {n}_{r} F}{R T} ( {η}_{n} + {U}_{n} ( {θ}_{n}^{s} ) - {U}_{S E I , r} ) ) . \qquad ( 35 )$$

Each reaction is thus governed by independent rate parameters {k_{SEI,r}, C_{SEI,r}, U_{SEI,r}, nᵣ}. However, a coupling is introduced through Uₙ(θₙ^{s}) which changes as a function of the total SEI current.

To model the diffusion-limited current densities, the diffusion parameters in Eq. 15 require reinterpretation, since each reacting species r must now diffuse through a solid SEI layer consisting of multiple solid reaction products. Here, we update our interpretation of the effective diffusivity to consider both the reacting molecule and its environment:

D_{SEI,r}: reacting molecule r through solid product l. (36)

With nᵣ reacting molecules and nₗ resulting solid products, we assume that nᵣ=nₗ according to Eq. 2, and therefore, D_{SEI,rl} is a matrix of size (nᵣ×nᵣ). To simplify the model, we introduce the notion of average diffusivities for each reacting species, according to:

$$\frac{1}{{\overline{D}}_{SEI , r}} = {\sum }_{l} \frac{{μ}_{l}}{{D}_{SEI , rl}} , \qquad ( 37 )$$

where D̅_{SEI,r} is the average diffusivity of reacting species r through a homogenized solid medium consisting of l solid products. μₗ=mₗ/Σₗmₗ are weights based on the mass of each solid product mₗ. In this representation, each reacting species r is assigned its own diffusivity which describes the diffusivity of species r through a homogenized environment consisting of nₗ solid products. The model thus carries only nᵣ number of D̅_{SEI,r}.

The diffusion-limited SEI current density can then be written as:

$${\tilde{J}}_{SEI , dif , r} = \frac{{\overline{D}}_{SEI , r} {c}_{SEI , r}^{0} {n}_{r} F}{{\overline{δ}}_{SEI}} . \qquad ( 38 )$$

The thickness of each SEI layer grows independently according to:

$$\frac{d {δ}_{SEI , r}}{dt} = {V}_{m , S E I , r} \frac{{j}_{SEI , r}}{{n}_{r} F} . \qquad ( 39 )$$

The total SEI thickness is taken to be the sum of each individual thickness:

$${\overline{δ}}_{S E I} = {\sum }_{r} {δ}_{SEI , r} . \qquad ( 40 )$$

In this representation, the thickness of each SEI is defined in a volume-averaged sense without making a distinction on the spatial arrangement of the SEI layers. The model thus remains zero-dimensional.

In summary, the multi-species SEI reaction model treats the solid SEI product as a zero-dimensional, homogenized medium with volume-averaged properties. While each SEI reaction is described by independent sets of rate parameters, the reactions become coupled since each reacting molecule must diffuse through the same medium and react at the same electrode surface. The homogenization approach taken for this Example enables the prediction of non-trivial SEI formation dynamics involving multiple electrolyte components, as will be detailed in Section 5.

### 4 Model Implementation

Equations from Table 1 were numerically integrated using a forward difference scheme. The simulation was run with a timestep of Δt=10 seconds. Each charge and discharge cycle takes less than 1 second to complete execution on a 2.6 GHz 6-Core Intel Core i7 processor. All code was written in Python and is publicly available at github.com/wengandrew/formation-modeling. The code is written to be modular and extensible, drawing from the design of other battery simulation software suites [Ref. 56, Ref. 57].

The simulation framework also supports constant voltage (i.e. potentiostatic) operation mode. During this charging mode, Eq. 3 is inverted to update the current for a given target voltage. The reduced-order representation of cell overpotentials allows for a closed-form solution of the form:

$${I}_{CV} = \frac{{V}_{t} - {U}_{p} + {U}_{n} - {\sum }_{i} {R}_{diff , i} {I}_{diff , i} exp ( - \frac{Δ t}{{τ}_{diff , i}} )}{{\sum }_{i} ( {R}_{ct , i} + {R}_{diff , i} ( 1 - exp ( - \frac{Δ t}{{τ}_{diff , i}} ) ) )} , \qquad ( 41 )$$

$$where {τ}_{diff , i} {=}^{Δ} {R}_{diff , i} {C}_{diff , i} .$$

TABLE 1
Equations describing the formation model.

| | | |
|---|---|---|
| Electrode dynamics | $\frac{d θ \text{?}}{dt} = - \frac{\text{?} ( t )}{{Q}_{p}} \frac{d {θ}_{o} ( t )}{dt} = + \frac{\text{?} ( t )}{Q \text{?}}$ | 6, 7 |
| | [symbol] = [symbol] − [symbol] + [symbol] + [symbol] | 3 |
| | [symbol] | 8 |
| | $\frac{\text{?} ( t )}{dt} = - \frac{1}{{τ}_{diff , i}} \text{?} ( t ) + \frac{1}{{τ}_{diff , i}} \text{?} ( t )$ | 9 |
| SEI reactions | [symbol] | 20, 22 |
| (EC only) | | |
| | $\text{?} = {( \frac{1}{\overline{j} \text{?}} + \frac{1}{\overline{j} \text{?}} )}^{- 1}$ | 17 |
| | $\text{?} = \text{?} exp ( - \frac{α \text{?} nF}{RT} ( \text{?} + {U}_{n} ( {θ}_{n} ) - {U}_{REI} ) )$ | 18 |
| | $\text{?} = \frac{nFD \text{?}}{\text{?}}$ | 19 |
| Solvent consumption | $\frac{d \text{?}}{dt} = - \frac{\text{?}}{nF}$ | 23 |
| Expansion | [symbol] (simplified) | 44 |
| | $\frac{d \text{?}}{dt} = V \text{?} \frac{\text{?}}{nF}$ | 26 |
| SEI boosting | [symbol] = [symbol] | 29 |
| | ${τ}_{i} \frac{dB}{dt} + B = γ \frac{d \text{?}}{dt}$ | 32 |
| Multi-species SEI | ${τ}_{i} \frac{dB}{dt} + B = 0$ | 32 |
| | $j \text{?} = \sum \text{?} = \sum \text{?} {( \frac{1}{\text{?}} + \frac{1}{\text{?}} )}^{- 1}$ | 33 |
| | $\text{?} = \text{?} exp ( - \frac{α \text{?} F}{RT} ( \text{?} + U \text{?} - U \text{?} ) )$ | 35 |
| | $\text{?} = \frac{D \text{?} F}{\text{?}}$ | 38 |
| | $\overline{D} \text{?} = {( {\sum }_{i} \frac{{p}_{i}}{D \text{?}} )}^{- 1}$ | 37 |
| | [symbol] | 40 |

[symbol]

indicates data missing or illegible when filed

Parameterization. Model parameters used for this Example are summarized in Table 2. Model parameters were either calculated based on the cell build parameters, taken from literature, fit to the experimental data, or assumed. Since parameter identification was not a focus of this Example, the parameters chosen for this Example may not be optimal.

SEI components. While the formation model supports simulating an arbitrary number of SEI-reacting species, we focus on studying a model system consisting of two SEI components: ethylene carbonate (EC) and vinylene carbonate (VC). These two components represent a subset of the experimentally-tested electrolyte (3:7 EC: DEC with 2 wt. % VC, see Section 2.1). Both EC and VC are also well-studied in literature, with established reaction pathways and some known model parameters [Ref. 9, Ref. 30, Ref. 58, Ref. 59]. VC, in particular, is present in a small quantity (2 wt. %) as an electrolyte additive and is known to be consumed during the formation process to help stabilize the SEI film [Ref. 60, Ref. 61, Ref. 62, Ref. 63]. VC, which reduces at ca. 1.35V [Ref. 58], is also markedly higher than EC, which reduces at ca. 0.8V [Ref. 9], and is thus expected to reduce first. VC thus provides a contrasting electrolyte component to understand both the capabilities and limitations of the model's ability to capture first-cycle reaction dynamics with multiple SEI components. EC and VC starting concentrations were calculated to match the experimental values. The EC reaction is given by Eq. 10. The VC reaction is given by [Ref. 64]:

$$2 V C + 2 {e}^{-} + 2 {Li}^{+} \to LVDC ↓ + {C}_{2} {H}_{4} ↑ , \qquad ( 42 )$$

where LVDC is lithium vinylene dicarbonate, the VC-derived SEI layer. Like EC and other solvents, multiple reaction pathways are possible, and each reaction may occur in multiple stages [Ref. 64]. However, for this Example, we simplify the representation by considering only Eq. 42 as the VC reaction scheme.

Electrode capacities. Electrode capacities Qₚ and Qₙ were initialized using a differential voltage fitting procedure outlined in Weng et al. [Ref. 65]. This method uses a C/20 charge voltage curve to extract information about electrode-specific capacities. The voltage curve used for this analysis was taken at the end of the two-week formation aging step. This Example assumes that the electrode capacities remain invariant throughout the formation process, i.e., no loss of active material. This assumption can be revisited as part of future work.

Initial conditions. Special attention was made to set the initial cell state prior to formation cycling. Before the formation cycles, we assumed that the negative electrode was fully delithiated (θₙ=0) and the positive electrode was fully lithiated (θₚ=1). The measured cell terminal voltage before formation was then used to constrain the set of possible half-cell potentials, according to:

$${V}_{t} {\vert}_{t = 0} = {U}_{p} ( {θ}_{n} = 1 ) {\vert}_{t = 0} - {U}_{n} ( {θ}_{p} = 0 ) {\vert}_{t = 0} . \qquad ( 43 )$$

For the cell under study, the full cell terminal voltage Vₜ was measured to be 635 mV before formation charging began. To identify the initial potentials of the positive and negative electrodes before formation, half-cells with lithium metal counter-electrodes were built. Half-cell potentials were measured immediately after electrolyte fill and assembly. The negative electrode (graphite) half-cells were measured to have potentials of {2.939, 2.925, 0.770, 1.698} V vs Li/Li⁺, and the positive electrode (NMC622) half-cells were measured to have potentials of {1.814, 2.813} V vs Li/Li⁺. The wide range of measured potentials measured suggest that more work is necessary to verify the initial half-cell potentials. For this Example, we picked Uₙ(θₙ=0)=2.00V and Uₚ(θₚ=1)=2.65V, which satisfies Eq. 43.

Half-cell potentials. Half-cell near-equilibrium potential functions Uₙ and Uₚ were adapted from Mohtat et al. [Ref. 10]. These curves were linearly extrapolated to satisfy the boundary condition given in Eq. 43. These functions are plotted in FIG. 13.

Expansion functions. Volumetric expansion functions for the positive and negative electrodes were taken from Mohtat et al. [Ref. 10] and shown in FIG. 13. For the simulations, a simplified version of Eq. 24 was implemented assuming constant and fitted prefactors, i.e.:

$${Δ}_{t o t} = {c}_{0} {δ}_{S E I} + {c}_{1} {v}_{p} ( {θ}_{p} ) + {c}_{2} {v}_{n} ( {θ}_{n} ) . \qquad ( 44 )$$

A future iteration of this Example could implement Eq. 24 directly by tuning Lₙ, Lₚ, and Rₙ, creating additional constraints used for model parameter tuning.

TABLE 1L
Variables, parameters, and initial conditions.

| Symbol | Definition | Value 1 | | Value 2 | | Untis | References |
|---|---|---|---|---|---|---|---|
| | SEI Properties | A | | B | | | |
| [symbol] | SEI reacting species | EC | | VC | | — | — |
| [symbol] | SEI solid product from species [symbol] | LEDC | | LVDC | | — | — |
| [symbol] | SEI reaction potential | 0.8 | | 1.35 | | V | [symbol] |
| [symbol] | SEI reaction current density | * | | * | | A m⁻² | Eq. 16 |
| [symbol] | Bulk phase concentration | 4541 | | 304.4 | | mol m⁻³ | Ref. 16 |
| [symbol] | Reaction rate constant | 3.0 × 10 [symbol] | | 7.0 × 10 [symbol] | | m s⁻¹ | [symbol] |
| [symbol] | Effective diffusivity of [symbol] in solid i = A′ | 4.2 × 10 [symbol] | | 4.2 × 10 [symbol] | | m² s⁻¹ | [symbol] |
| [symbol] | Effective diffusivity of [symbol] in solid i = B′ | 6.6 × 10 [symbol] | | 6.6 × 10 [symbol] | | m² s⁻¹ | [symbol] |
| [symbol] | SEI capacity of the [symbol] th species | * | | * | | A s | Eq. 21 |
| [symbol] | SEI molar volome | 9.585 × 10⁻⁵ | | 5.810 × 10⁻⁵ | | m³ mol⁻¹ | Ref. 16 |
| [symbol] | SEI growth [symbol] time constant | 10 | | 10 | | mins | [symbol] |
| [symbol] | SEt growth de- [symbol] time constant | 100 | | 100 | | mins | [symbol] |
| [symbol] | SEI boosting input sensitivity [symbol] | 2.4 × 10 [symbol] | | 2.4 × 10 [symbol] | | s m⁻¹ | [symbol] |
| | Electrode Potentials | pos. | | neg. | | | |
| [symbol] | electrode potential vs Li/Li⁺ | 2.635 | (I.C.) | 2.000 | (I.C.) | V | [symbol] |
| [symbol] | electrode lithium stoichiometry | 1.0 | (I.C) | 0.0 | (I.C.) | — | Ref. 10** |

| [symbol] | electrode maximum capacity | 2.95 | 3.14 | | Ah | Based on Ref. 66 |
|---|---|---|---|---|---|---|
| | Electrode Overpotentials | pos. | neg. | | | |
| [symbol] | electrode over-potential vs Li/Li⁺ | * | * | | V | Eq. 8 |
| [symbol] | electrode diffusion current (through [symbol] ) | * | * | | Å | Eq. 9 |
| [symbol] | electrode charge-transfer resistance | 0.01 | 0.01 | | Ω | Assumed |
| [symbol] | electrode diffusion resistance | 0.001 | 0.001 | | Ω | Assumed |
| [symbol] | electrode diffusion capacitance | 7.6 × 10 [symbol] | 7.6 × 10 [symbol] | | [symbol] | Assumed |
| [symbol] | electrode diffusion time constant | * | * | | s | Assumed |
| | Electrode Geometry and Expansion | pos. | neg. | | | |
| [symbol] | electrode specific surface area [symbol] | — | 1.05 × 10⁵ | | m⁻¹ | Assumed |
| [symbol] | electrode geometric area | — | 0.097566 | | m² | Caculated |
| [symbol] | elcetrode geometric length | — | 80 | | μm | Assumed |
| [symbol] | expansion fitting coefficient | — | 127 | | — | [symbol] |
| [symbol] | expansion fitting coefficient | — | 0.00045 | | — | [symbol] |
| [symbol] | expansion fitting coefficient | — | 0.00045 | | — | [symbol] |
| [symbol] | microscopic pouch cell thickness expansion | — | — | | m | Eq. 24 |
| [symbol] | electrode particle volumetric expansion | * | * | | | Ref. 10 |
| [symbol] | SEI thickness expansion | — | 5 × 10⁻⁹ | (I.C.) | | Eq. 26 |

Asterisks (*) indicate values computed during simulation run-time, “I.C” indicates an initial condition. Double asteriks (**) indicate that values were modified from the literature values. [symbol]
indicates data missing or illegible when filed

### 5 Model Results

The formation model was simulated by inputting the current profile from FIG. 1B. The results highlight some of the key characteristics of a two-component SEI growth mechanism involving the sequential reduction of VC followed by EC. The observed results underscore the coupled nature of SEI formation dynamics, including the interplay between cell expansion and boosted SEI growth, as well as the interplay between reaction dynamics involving multiple SEI components. The same results introduced here will also set the stage for comparison against experimental data which will be discussed in Section 6.

### 5.1 SEI Growth Dynamics During First Charge

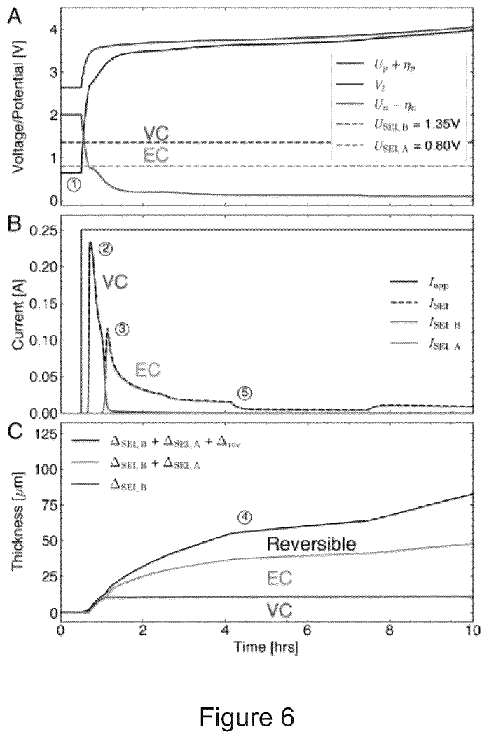

FIG. 6 highlights key model outputs before and during the first formation charge. The simulation begins with the cell at rest before any external charge is applied. At this stage, the positive electrode is completely lithiated (θₚ=1) and the negative electrode is completely delithiated (θₙ=0). Negligible SEI growth occurs during this stage since the negative electrode potential of 2.0V vs Li/Li⁺ exceeds the reaction potentials of both VC and EC (Panel A, marker 1). After 30 minutes, an external current of C/10 (0.25A) is applied to begin the formation charge process (Panel B). Within minutes, the negative electrode potential drops below the VC reaction potential of 1.35V and VC begins to reduce (marker 2). This reaction current reaches a peak within minutes and falls back down. Next, as the negative electrode becomes more lithiated, the negative electrode potential falls below the EC reaction potential of 0.80V and EC begins reducing (marker 3). Similar to VC, the reaction current for VC also soon reaches a peak, but then gradually decreases.

The buildup of VC and EC-derived SEI products during the initial stages of formation contributes to the macroscopically-observed cell thickness expansion (Panel C). The predicted total expansion is a result of both the irreversible expansion due to SEI growth and the reversible expansion due to lithium intercalation/deintercalation in the electrodes. The model predicts that SEI growth plays a dominant role in determining the total cell expansion during the first cycle.

During the first charge cycle, the negative electrode expands, activating the SEI growth boosting mechanism which increases the effective SEI diffusivity (see Section 3.7). Since the negative electrode expansion increases monotonically during the charge cycle, boosting persists throughout the cycle. Note that, at mid-SOCs, the expansion rate for the lithiated graphite is lowered (marker 4) which decreases the boost magnitude according to Eq. 32. The EC reduction current decreases accordingly (marker 5). The boosting mechanism will be explored in more detail in Section 5.3.

### 5.2 Exploring the Limiting Current

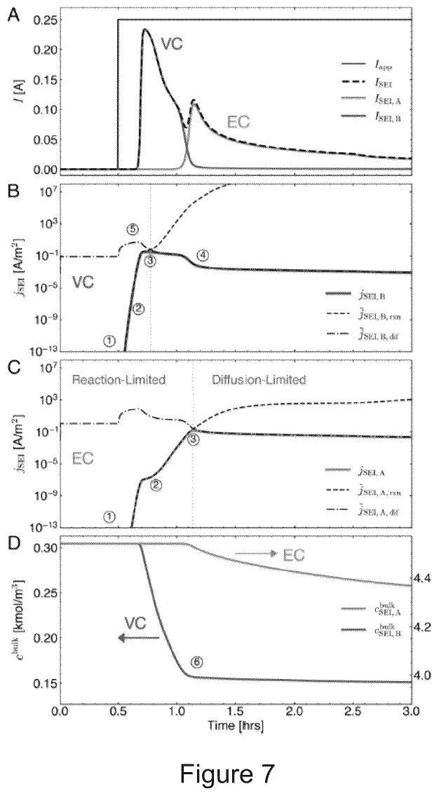

FIG. 7 explores the limiting SEI current during the initial stages of formation. Before any external current is applied, the SEI currents are reaction-limited since the negative electrode, at 2.0V vs Li/Li⁺, is above the reaction potential for both VC (1.35V) and EC (0.8V) (marker 1 in both FIGS. 6 and 7), so Eq. 11 would predict very small current densities. However, after the external current is applied, the negative electrode potential decreases rapidly due to the steepness of the negative electrode equilibrium potential function Un. This decreases the SEI reaction overpotential (Eq. 14) towards more negative values, increasing the overall SEI current (Eq. 11). This process explains why the initial surge in SEI current coincides with the rapid decrease in the negative electrode potential (marker 2 in both FIGS. 6 and 7). The reacting species with the higher reaction potential will tend to react first, as was the case with VC and EC in this model system.

### 5.2.1 Transition from Reaction-Limited to Diffusion-Limited SEI Growth

After the initial surge in SEI current, the SEI currents reach a peak and then begin to decrease. This can be observed for both the VC and EC reactions (marker 3 in FIG. 7). We attribute this SEI current decay to the transition from a reaction-limited regime to a diffusion-limited regime. During this transition, the reaction-limited current continues to increase as the negative electrode potential continues to decrease. However, simultaneously, the diffusion-limited current decreases as the SEI film thickness increases according to Eq. 26. This film thickness increase limits the concentration of reacting molecules at the electrode surface. Eventually, the diffusion-limited current drops below the reaction-limited current. After this point, further increases in the reaction kinetics are no longer fully realized and the total reaction current begins to follow the diffusion-limited current (Eq. 19). The diffusion-limited current continues to decrease as the SEI film builds, limiting the overall SEI reaction rate.

### 5.2.2 Multi-Species Diffusive Coupling and Boosted SEI Growth

After 1.2 hours, the VC reaction current density experiences another drop (marker 4 in FIG. 7). This drop is due to the coupling between the EC and VC diffusivities introduced by the multi-species reaction model (see Section 3.8). As EC begins to react, the EC-derived film begins to grow. For this simulation, the effective diffusivity of the EC-derived film was assumed to be two orders of magnitude lower than that of the VC-derived film (see Table 2). After the EC reaction begins, the effective diffusivity of VC through the SEI, which now consists of both the VC and EC-derived films, is pulled towards the lower diffusivity of the EC-derived film, causing the VC reaction rate to be further slowed.

The effect of the boosted SEI growth mechanism is again observed in FIG. 7, Panels B,C. The diffusion-limited currents here do not monotonically decrease as would be predicted by Fick's law. Rather, the diffusion-limit current initially surges when external current is applied (marker 5). This surge is explained by the negative electrode expansion which modifies the SEI diffusivity according to Eqs. 29 and 31. The diffusion-limited current decreases shortly thereafter as the SEI film thickness begins to increase. See Section 5.3 for a further discussion on SEI boosting.

### 5.2.3 Solvent Consumption

FIG. 7, Panel D plots bulk concentrations for EC and VC. Solvent and additive consumption occur due to SEI growth according to Eq. 23. The initial concentration of VC is much lower than that of EC (304 mol/m³ versus 4541 mol/m³) since VC is an electrolyte additive. VC is consumed rapidly during the initial stages of the first charge cycle. However, VC consumption appears to plateau afterwards (marker 6). This plateau coincides with the start of EC reduction, which depresses the VC reduction rate due to the diffusive coupling as previously explained. Hence, the VC concentration does not drop completely to zero during formation charge due to diffusion limitations. The model thus predicts the presence of trace amounts of electrolyte additives after formation cycling is completed.

### 5.3 Understanding SEI Growth Boosting

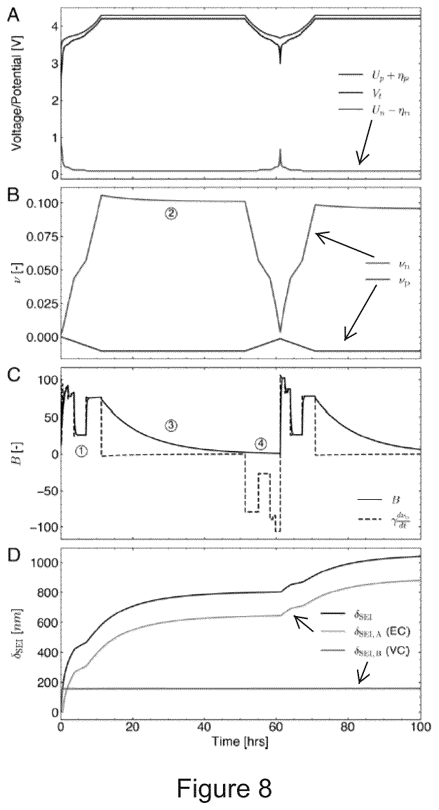

FIG. 8 highlights the impact of boosting on the SEI growth rate. For this simulation, the cell was first charged at C/10 to 100% SOC, rested for 40 hours, then discharged at C/10 (Panel A). This pattern was then repeated. During each charge and discharge cycle, the negative electrode expands and contracts (Panel B). The negative electrode volumetric expansion rate, dvₙ/dt, provides a non-linear input which activates the boosted SEI mechanism (see Section 3.7).

Panel C plots B(t) along with γ(dvₙ/dt). During charging, B(t) and γ(dvₙ/dt) track closely with each other since we have assumed a small value for the boosting time constant, with τ_{↑}=10 mins. The step transitions (marker 1) are due to the piecewise-linear construction of the negative electrode expansion function, vₙ, consisting of three regions: steep, shallow, and steep, corresponding to low, medium, and high lithium stoichiometries, respectively (see FIG. 13). The SEI thickness growth rate tracks these different regions accordingly, initially starting fast, then slowing down, then becoming fast again (Panel D).

During rest, γ(dvₙ/dt) approaches zero, but it is not exactly zero, since lithium continues to deintercalate from the negative electrode to form SEI during rest, causing the negative electrode to contract slightly (marker 2). Overall, the magnitude of dvₙ/dt during resting remains small. B(t), however, takes hours to decay from its boosted state since we assumed that the de-boosting process is much slower than the boosting process, with τ_{↓}=100 mins (marker 3).

As the rest step transitions into a discharge step, γ(dvₙ/dt) inverts sign, but B(t) continues to exponentially decay towards zero (marker 4). Physically, this behavior represents the assumption that, as the negative electrode particles contract, the SEI maintains physical contact with the particle and no new reaction surfaces are exposed. As the previously-exposed negative electrode surfaces rebuild SEI, the SEI effective diffusivities return to their nominal values prior to boosting.

Panel D highlights the effect of boosted SEI growth on SEI thickness expansion. During charging, the SEI build-up is accelerated. However, during resting and discharging, the SEI growth rate slows down, corresponding to a steady-state diffusion regime. During the subsequent charge, this steady-state regime is interrupted as the SEI growth rate is boosted again by the charging process.

### 6 Comparison to Experiment

One goal of this Example was to develop a model capable of capturing macroscopic trends observed in experimental formation data. Here, we demonstrate that our formation model achieves this goal for a range of metrics, including full cell voltages, cell thickness expansions, coulombic efficiencies, and first cycle dQ/dV.

### 6.1 Full Cell Voltage

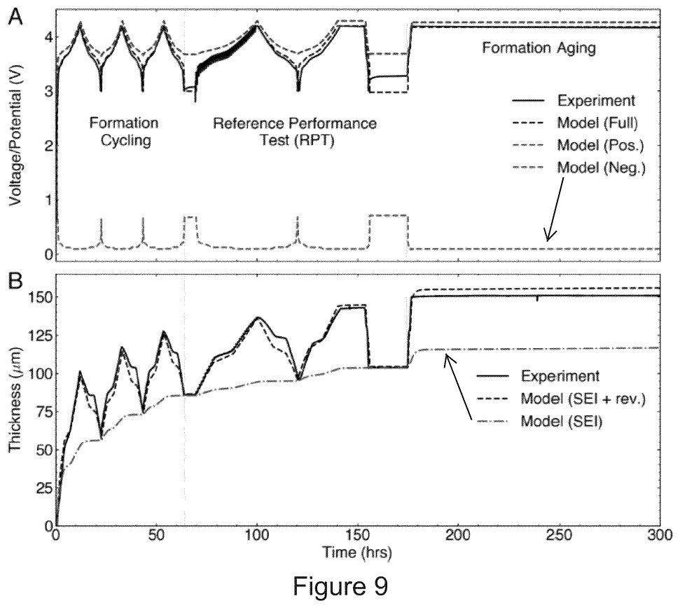

FIG. 9, Panel A compares the modeled versus measured full cell voltage during and after the formation cycles. Model-predicted positive and negative electrode potentials vs Li/Li⁺ are also shown for reference. The simulation was run using the parameters described in Section 4 and with a current input that matches the experimental data. The result shows that the formation model outputs generally match the observed voltage trends over the course of the formation charge-discharge cycles and during the subsequent formation aging step.

However, despite the general agreement between model and experiment, several model mismatches can be observed. First, the cell voltage was under-predicted during the three formation discharge steps. This may be due to the fact that the half-cell equilibrium potential functions [Ref. 10] were based on charge curves and thus do not account for hysteresis effects [Ref. 66, Ref. 67, Ref. 68]. The half-cell equilibrium potential functions were also inherited from a previous work [Ref. 10] which had similar but not identical positive and negative electrode compositions. Next, the voltage rebound at 0% SOC was not predicted by the model. This model mismatch is attributed to the fact that our overpotential model uses a cell resistance does not vary with SOC, yet it is well-known that cell resistance increases significantly at lower SOCs owing to kinetic limitations in the NMC positive electrode [Ref. 31, Ref. 69, Ref. 70, Ref. 71].

### 6.2 Full Cell Expansion

FIG. 9, Panel B compares the modeled versus measured full-cell thickness expansion during and after the formation cycles. The model-predicted irreversible expansion due to SEI growth is also shown as a green dashed line. The model captures macroscopic trends in both irreversible and reversible full-cell expansion, across formation cycles and subsequent formation calendar aging. Consistent with the experiment, the model correctly predicts that the irreversible expansion slows down during the formation aging step. This result was achieved by using the boosted SEI growth formulation which accelerates the SEI growth process during cycling (see Section 3.7).

As with the voltage data, some model mismatches persist. First, the model over-predicts the electrode contraction at mid-SOCs during discharging steps. The origin of this mismatch is unclear, but we hypothesize that the graphite expansion function may also be subject to charge-discharge asymmetry. In this Example, the expansion functions were parameterized on charge, not discharge [Ref. 10], so the model would not be able to capture this hysteresis effect. Another model mismatch occurs during the formation aging step. While the model correctly captures the slope of the expansion data, the model ‘over-boosted’ the SEI growth rate, and thus the total expansion, during the C/2 charge leading up to the formation aging step. This result suggests that the first-order representation of the boosting mechanism given by Eq. 32 may be insufficient to capture the dynamics of boosting at all C-rates. Thus, while the SEI growth boosting mechanism represented in this Example remains a reasonable starting point to capture expansion differences between cycling and calendar aging, there remains room to improve the representation of higher-order dynamical effects such as the effect of cycling C-rates.

We finally note that active material loss mechanisms are not currently represented in the model, which could contribute to another source of model error. As the electrodes lose active material, e.g., due to loss of electronic conduction pathways, or due to material phase transformations, the lost active material will no longer participate in reversible expansion, decreasing the overall observed reversible expansion. Finally, similar to the equilibrium potential functions, the volumetric expansion functions vₙ and vₚ are also inherited from literature [Ref. 10] and may not be exact, contributing to yet another possible source for model error.

### 6.3 Formation Coulombic Efficiencies

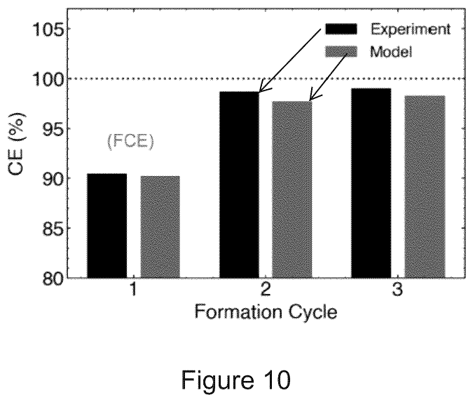

FIG. 10 compares the modeled versus measured FCE during the first formation cycle as well as the CE of the subsequent two cycles, defined by Eq. 1. The formation model predicted the FCE within 1 percentage point of the measured result. However, the model underestimated the CE of the next two cycles. The model mismatches here are attributed to suboptimal parameter tuning which can be improved with further optimization.

Overall, the formation model not only predicted that the FCE is much lower than the CE of subsequent cycles, but the model also gave an intuitive explanation for why this is necessarily the case: the first charge cycle is the only cycle that sees reaction-limited SEI growth. After the first charge cycle, the SEI reaction becomes diffusion-limited, slowing down the SEI reaction rate for all subsequent cycles (see Section 5.2.1).

### 6.4 Formation Charge dQ/dV

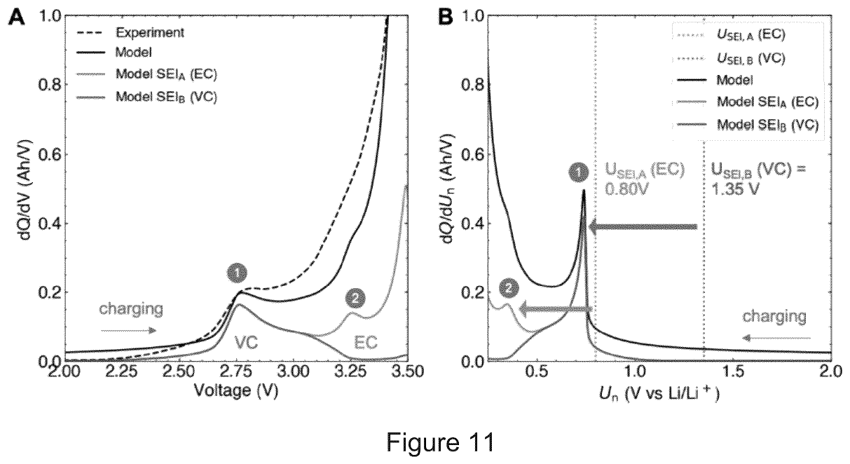

FIG. 11, Panel A compares the model vs measured full cell dQ/dV curve during the first formation charge. The plot represents the incremental capacity accumulated by the cell at each increment of full cell voltage. This plot is experimentally observable, with the measured result plotted as a dashed line. This plot is commonly studied in electrolyte development studies since peaks in dQ/dV during the initial formation charge cycle can often be attributed to SEI-forming electrolyte reduction processes. However, care is usually needed in interpreting the data since the dQ/dV peaks can also be due to shifts in the solid-phase potentials as the positive electrode is delithiated and the negative electrode is lithiated.

In the experimental data, a dQ/dV peak was observed at approx. 2.8V (marker 1). The formation model attributed this peak to the reduction of the VC additive. The model predicted the position of this reduction peak and also qualitatively captured the peak shape. The model additionally predicted a second, broad peak, corresponding to EC reduction (marker 2). However, the EC peak was not observed in the experimental data. This model mismatch may be due to differences in the electrolyte composition: the experimental data was obtained with an electrolyte comprising both EC and DEC, but the model only represented EC.

### 7 Discussion: Mechanistic Insights

The formation model developed in this Example provides a quantitative understanding of what makes the first formation charge process different from all subsequent cycles in lithium-ion battery systems. This understanding holds important practical implications as well as mechanistic insights, which we discuss in this section.

### 7.1 What is Special About the First Formation Charge?

Minimal SEI growth prior to formation charge. The formation model predicts that SEI growth does not begin until the cell is externally charged for the first time. Before the charge step, the SEI formation process is suppressed according to Eq. 11 since the negative electrode potential, at ca. 2.0V, is above the reaction potentials for the reacting molecules studied for this Example (0.8V for EC and 1.35V for VC). This observation has some practical implications: since SEI formation only begins when the cell is charged, the duration elapsed between electrolyte filling and the first formation charge cycle may be discounted as a potential source of variability in SEI properties and subsequent cell performance. Note, however, that copper dissolution at high negative electrode potentials, which may occur during the time between electrolyte filling and formation charge [Ref. 72, Ref. 73], creates a separate source of variability that warrants further study using the formation model.

Reaction-limited SEI growth occurs exclusively during formation charge. The first cycle efficiency (FCE) during formation is typically between 80% to 90% and can vary as a function of the electrolyte system [Ref. 74], negative electrode type [Ref. 74], and formation protocol [Ref. 72]. The FCE is thus much lower than subsequent measures of CE which typically exceeds 99%. This result was experimentally replicated in our formation dataset and was also predicted by our formation model, see FIG. 10. The formation model provides a simple explanation to why the FCE is low compared to the CE of subsequent cycles: the first formation charge is the only time the SEI growth process is reaction-limited. After the first charge cycle, SEI growth becomes diffusion-limited (see FIG. 7). Intuitively, the SEI film is the thinnest during the first formation charge, making solvent diffusion facile. During the first formation charge, a sufficient amount of SEI is built up and the SEI reaction becomes self-limiting due to diffusion limitations. For the remaining life of the battery, the SEI reaction remains diffusion-limited. This result suggests that the effective SEI diffusivity, D_{SEI}, is a key parameter describing the passivation of the SEI over a battery's life. A low effective SEI diffusivity is thus essential for creating a long-lasting battery. By contrast, the SEI kinetic rate parameter, k_{SEI}, appears to only play a role in determining the SEI formation dynamics during the first charge cycle. The model predicts that k_{SEI} becomes inconsequential to the SEI growth rate during later formation cycles and for the rest of the cell's life.

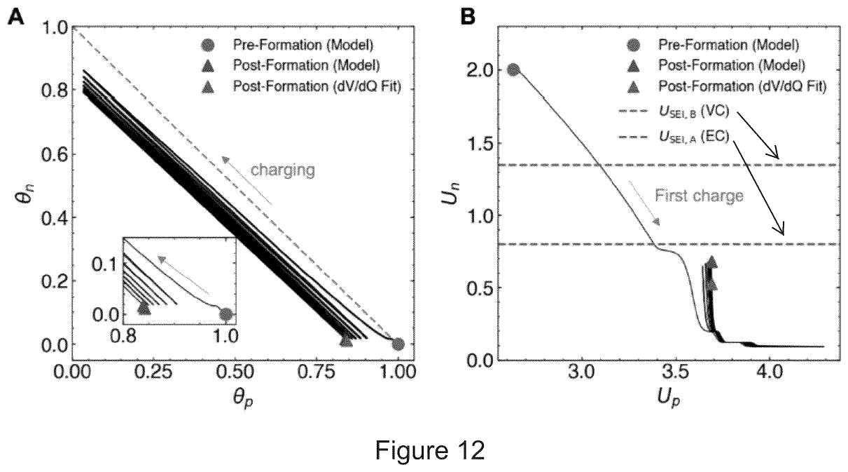

Extended lithium stoichiometric ranges and electrode surface potentials. FIG. 12 shows how the lithium stoichiometries in each electrode evolve during and after the formation cycles (Panel A), along with their corresponding electrode potentials (Panel B). Before the first formation charge, the negative electrode is completely empty of lithium (θₙ=0) and the positive electrode is completely full of lithium (θₚ=1), shown in red circles. After formation completes, neither electrode will be able to access these initial lithium stoichiometries and their corresponding electrode potentials. Notably, the maximum accessible lithium stoichiometry in the positive electrode continues to decrease over the RPT and formation aging (Panel A inset) due to the irreversible consumption of lithium from the positive electrode to form the SEI. By the end of the formation aging step, the maximum positive electrode stoichiometry has decreased from 1.0 to ca. 0.8 (blue triangles). Meanwhile, the minimum negative electrode potential has also increased from 0.0 to ca. 0.018. In both electrodes, these permanent shifts in the accessible lithium stoichiometry range also restrict the range of electrode potentials observable after formation completes (Panel B). The negative electrode starts at 2.0V vs Li/Li⁺ before formation, but by the time the first formation charge completes, the negative electrode will never see potentials above 0.7V vs Li/Li⁺. These restrictions in electrode potentials may not bear much consequence to the overall SEI reaction rate over life, since the SEI reactions will be primarily driven by diffusion limitations as explained in Section 5.2.1. However, this result does explain why copper dissolution, which occurs at high negative electrode potentials, is a concern during the formation process but is less of a concern over the remainder of a battery's life.

### 7.2 Reinterpreting dQ/dV Peaks for SEI Reaction Studies

Returning to FIG. 11, Panel B shows a dQ/dV plot where the differential capacity is plotted against the differential negative electrode equilibrium potential Un-This result is discussed briefly now to gain further insight into the rate-limiting mechanisms during formation charge. A key observation here is that the position of the reduction peaks for both EC and VC do not indicate their respective reaction potentials, as is often assumed in previous literature studies. Rather, there is a delay between the reaction potentials and the respective reduction peaks. For example, the VC reaction potential is at 1.35V, yet the observed dQ/dV peak does not occur until the negative electrode has dropped below 0.8V. Similarly, the EC reaction potential is at 0.8V, but its corresponding dQ/dV peak occurs below 0.4V. This delay suggests that the dQ/dV peaks do not indicate the reaction potentials; rather, the peak indicates the transition from the reaction-limited to the diffusion-limited regime, which occurs sometime after the negative electrode potential falls below the reaction potential (see FIG. 7). This result partly explains why literature reports of SEI reaction potentials, U_{SEI}, can vary widely.

### 7.3 Analyzing Rate-Liming Regimes

The transition from reaction-limited SEI growth to diffusion-limited SEI growth appears to be a key characteristic of the first formation charge cycle. Due to its importance, we briefly discuss some analytical approaches for further characterizing this transition to promote future investigations in this area.

We define a dimensionless number, Bu, as:

$$Bu {=}^{Δ} \frac{{\tilde{J}}_{SEI , rxn}}{{\tilde{J}}_{SEI , dif}} , \qquad ( 45 )$$

Bu characterizes the ratio of SEI current carried by the reaction versus the diffusive process. When Bu<<1, the SEI current is reaction-limited, and when Bu>>1, the SEI current is diffusion-limited. Bu can be found by substituting Eqs. 18 and 19 into Eq. 45,yielding:

$$Bu = \frac{{k}_{rxn}}{{k}_{dif}} , \qquad ( 46 )$$

$$where :$$

$${k}_{rxn} {=}^{△} {k}_{SEI} exp ( - \frac{{α}_{SEI} F}{RT} {η}_{SEI} ) \qquad ( 47 )$$

$${k}_{dif} {=}^{△} \frac{{D}_{SEI}}{{δ}_{SEI}} . \qquad ( 48 )$$

kᵣₓₙ is the apparent reaction-limited rate parameter which depends on both the pure rate constant k_{SEI} as well as the reaction over-potential η_{SEI}=f(Uₙ, U_{SEI}). k_{dif} is the apparent diffusion-limited rate parameter which accounts for both the effective diffusivity as well as the film thickness. These rate parameters clarify that the rate-limiting process depends on both internal material properties, such as k_{SEI} and D_{SEI}, as well as external factors such as Uₙ and δ_{SEI}.

### 7.4 Implications of SEI Growth Boosting

The boosted SEI growth mechanism and its mathematical representation were key developments enabling the model to capture experimental trends during both formation cycling and formation aging (see Sections 3.7, 5.3). Here, we further clarify the modeling assumptions and physical implications of the SEI boosting mechanism, highlighting its role in enabling the formation model to be extended towards general-purpose cycle life and calendar aging simulations.

Necessity. A key insight from this Example was that a boosted SEI growth mechanism during charging was necessary to capture the macroscopic trends in capacity fade and cell expansion during formation cycling and formation aging. Without the boosted SEI mechanism, the model could only fit formation cycling and aging using separate parameter sets, but not both using the same parameter set. Specifically, without boosting, SEI diffusivities that explained the voltage and expansion data during formation cycling led to unrealistically high degradation rates during formation aging. Conversely, an SEI diffusivities that explained the voltage and expansion data during formation aging was too small to explain the cell expansion trend during formation cycling. When the boosted SEI growth mechanism was introduced, both formation cycling and aging were explained by the same set of SEI diffusivities (see FIG. 9). Introducing the boosted SEI mechanism thus enabled a unified representation of SEI growth rates across cycling and storage.

Reaction rate asymmetry. The boosted SEI growth mechanism also introduces a source of reaction rate asymmetry: SEI growth is predicted to occur more quickly during charging (negative electrode lithiation) compared to discharging (negative electrode delithiation). This result is consistent with experimental results from Attia and Das [Ref. 59, Ref. 75]. The boosting mechanism frames the reaction rate asymmetry as a particle stress-driven phenomenon whereby reaction rates are boosted only when the SEI expansion but not when it shrinks. Boosting thus provides a unified description of the apparent SEI reaction rate asymmetry described in earlier works.

Capacity fade does not trend with square root of time. Attia et al. [Ref. 33] reported that experimental data on lithium-ion battery degradation often did not strictly follow a \sqrt{t} relationship, as would be expected with diffusion-limited SEI growth. The boosted SEI growth mechanism provides a quantitative description of why the \sqrt{t} relationship is violated, and more specifically, why the exponent is often more than 0.5. During charging, the boosting mechanism enhances the SEI reaction rate, taking the system out of the steady-state diffusion regime. The \sqrt{t} dependence can thus be viewed as a limiting case where the boost factor γ is zero.

Model representation. In our model, the SEI growth boosting process was represented as a modification to the effective diffusivity D_{SEI}. In reality, the effective reaction rate parameter k_{SEI} could also be boosted since the reaction surface area could increase during SEI cracking. However, in the model, increasing k_{SEI} will have little impact on the SEI growth rate beyond the initial formation charge cycle since the SEI growth process becomes diffusion-limited by the end of the first cycle (see FIG. 7). Overall, our treatment of SEI growth boosting remains phenomenological: the model captures the macroscopic trends in voltage and expansion without elucidating the mechanistic details of the SEI boosting process. Such mechanistic details would be more appropriate to address using higher-fidelity models.

### 8 Applications

This Example focused on developing the mathematical preliminaries necessary for building practical models of the battery formation process. Towards this end, we adopted a ‘dual-tank’ model to contextualize the SEI formation process within a full cell system. We believe that this level of representation captures enough physically-relevant processes to yield useful predictions while being simple enough to make parameter-tuning feasible. Ultimately, the SEI growth dynamics predicted by the model bear measurable consequences to the initial cell state, including the FCE, the initial cell capacity, and long-term degradation trajectories. We thus envision that this model can be deployed towards several applications in cell manufacturing, including formation protocol optimization, electrolyte design, cell lifetime prediction, and degradation model parameter identification. This section describes these future applications and identifies relevant next steps to realize these applications in practice.

### 8.1 SEI Passivation and SEI Diffusivity as Cell Lifetime Indicators

Perhaps the most important role of battery formation is to create a so-called ‘passivating SEI.’ Such an SEI would minimize further SEI reactions after the formation process completes, leading to a longer-lasting cell. A more passivating SEI is typically considered to be more dense or less porous [Ref. 30]. Conversely, a less passivating, or ‘non-passivating’ SEI, is assumed to be less dense or more porous.

The formation model represents the concept of SEI passivation through the homogenized effective SEI diffusivity, D̅_{SEI,r}, see Eq. 37. This parameter encapsulates the effect of SEI porosity according to Eq. 28: a less porous, more passivating SEI will have a lower D̅_{SEI,r}. Our model therefore interprets the formation of a passivating SEI as the formation of an SEI that minimizes D̅_{SEI,r}. Note that the SEI reaction rate parameter, k_{SEI}, does not play a role in determining SEI passivation since the system becomes diffusion-limited at the end of the very first formation charge cycle (see Section 5.2.1).

The formation model eludicates how SEI passivation can be tuned: D̅_{SEI,r} depends on both the electrolyte composition and the formation protocol. The electrolyte composition sets the individual solvent diffusivities, D_{SEI,rl}, which are material properties that may be tunable through electrolyte engineering. Meanwhile, the formation protocol can be used to tune how much time is spent at each negative electrode potential. In theory, the formation protocol can be designed to preferentially reduce one particular electrolyte component associated with a low diffusivity, resulting in an overall more passivating SEI film without changing the electrolyte composition.

To summarize, the formation model can be used to predict how electrolyte composition and formation protocols can influence SEI passivation, which ultimately sets the long-term SEI growth rate and hence the cell lifetime. It is contemplated that one could focus on exploring the sensitivity of electrolyte composition and formation protocols on the resulting SEI diffusivities.

### 8.2 Direct Lifetime Simulations and Path-Dependent Aging

In addition to predicting cell lifetime indicators such as SEI passivation, we envision that the formation model can be used to directly simulate cell lifetime. This can be done by extending the simulation time domain to include cycling and calendar aging conditions after the formation process completes. The simulation can, in theory, be run until the cell capacity drops below some minimum threshold, which could encompass hundreds or thousands of cycles with varying usage profiles. We expect that such usage of the formation model is valid since SEI growth is generally understood to be the dominant degradation mechanism in many commercial lithium-ion systems and under typical use cases [Ref. 31, Ref. 76].

Using the formation model to directly simulate aging confers several advantages. First, the formation model provides a consistent representation of an essential degradation process—SEI growth—during the formation process and over the remainder of a cell's life. The resulting simulation therefore bridges the gap between battery manufacturing process understanding and resulting cell lifetime performance. Second, the formation model captures path-dependent aging through the boosted SEI growth mechanism. With this mechanism, the boost sensitivity factor, γ, from Eq. 32 can be viewed as a ‘cycling loss sensitivity’ factor. As γ approaches zero, no SEI growth boosting occurs during cycling and the diffusion process remains under steady-state. Under this condition, the cell experiences only calendar aging losses. Such a scenario could describe ‘power cells’ having high electrode porosities and low energy densities. Meanwhile, as γ increases, the SEI growth process during cycling becomes boosted, so the cell becomes more sensitive to damage during cycling. Such a scenario could describe ‘energy cells’ having low electrode porosities and high energy densities. With the boosting mechanism, dynamical changes to the aging profile, including transitions between cycling and aging conditions, are naturally represented by the model. Finally, the formation model, being a zero-dimensional model, is fast to run, making it suitable for lifetime simulations which often involve simulating hundreds to thousands of cycles.

The formation model simulation framework already allows for the simulation of arbitrary cycling and calendar aging profiles. It is contemplated that one could therefore focus on further validating simulation results against experimental lifetime data. Gaps identified between modeled versus measured results could motivate further model developments, which could include refining the boosted SEI growth mechanism representation, including other degradation modes beyond SEI growth such as active material losses, and improving the numerical implementation.

### 8.3 Formation Protocol Optimization and Electrolyte Design

Since the formation process is time and energy-intensive, battery manufacturers are incentivized to decrease the time taken for the formation and aging process [Ref. 2, Ref. 77]. But how does decreasing formation time affect SEI passivation? The formation model clarified how SEI passivation during formation depends on both electrolyte properties (e.g., electrolyte composition, additive amount, diffusivities, reaction potentials, rate constants) and the formation protocol (e.g., time spent at different negative electrode surface potentials, the negative electrode expansion rate). Identifying which of these parameters more strongly influence cell characteristics (e.g., FCE, initial cell capacity, long-term degradation rates) can help inform both electrolyte design and formation protocol design. One particular question that may be answered is: “how much influence does the formation protocol have on determining initial cell characteristics?”

It is contemplated that the model-based formation protocol optimization could focus on further validating model outputs against ‘fast formation’ protocols already proposed in literature [Ref. 31, Ref. 78]. Similarly, predictions made for different electrolyte compositions and properties could also be further validated against experiments.

### 8.4 Degradation Model Parameter Identification

Physics-based battery degradation models are typically tuned, or calibrated, against cycling and calendar aging data. See, for example, work by Reniers et al. [Ref. 57]. These experimental datasets are collected on cells after formation has already completed. Our Example introduces an opportunity to leverage a new dataset—formation cycling and aging—to improve model parameter identification. The degradation parameters from the formation model (e.g., U_{SEI}, D_{SEI}, k_{SEI}) may be directly transferable to other modeling contexts such as the Single Particle Model [Ref. 79, Ref. 80] and the full Doyle-Fuller-Newman (or P2D) model [Ref. 46, Ref. 81]. The experimental formation data provides additional, physically-relevant features, such as voltage traces during formation cycling and aging (FIG. 3), the FCE (FIG. 10) and the first charge dQ/dV (FIG. 12), which all serve to constrain the set of possible degradation model parameters. Additionally, macroscopic expansion measurements can also be used to tune electrode parameters such as particle sizes and electrode dimensions (Eq. 24) as well as SEI properties such as SEI molar volume (Eq. 26).

An expected obstacle for model parameter identification relates to the problem of parameter uniqueness, or parameter identifiability. Even with our reduced-order SEI growth representation, each electrolyte component is described by at least 4 intensive material properties: D_{SEI}, U_{SEI}, k_{SEI}, and V_{m,SEI}. While the presence of expansion measurements is expected to improve the identifiability of some parameters, it may still not be enough to identify all of the parameters. More ex-situ characterization may thus be beneficial to reduce the number of model parameters that need tuning. Based on this Example, it is contemplated that one could first understand model parameter sensitivity, to answer the question: “which model parameters have the greatest impact on observed cell characteristics such as FCE, initial capacity, and degradation rates?”

### 9 Conclusions

This Example develops a reduced-order electrochemical model of the formation cycling and aging process for lithium-ion batteries. The model supports simulating an arbitrary number of electrolyte components that react at the negative electrode surface to form a composite SEI film with volume-averaged properties. The model also tracks electrode-level lithium stoichiometries and potentials, enabling the tracking of SEI current densities as a function of full-cell voltages. The model further couples an electrode expansion model which accounts for both reversible and irreversible expansion. We finally introduce an SEI growth boosting mechanism which enabled a unified description of SEI growth during both formation cycling and formation calendar aging. We demonstrated that the formation model qualitatively matched experimental formation data, including cell voltages, cell expansion, coulombic efficiencies (including first cycle efficiency, or FCE), and the dQ/dV curve during the first charge cycle which indicated the reduction of the VC electrolyte additive.

The formation model clarified why the first formation charge cycle is special. First, SEI growth does not begin until external current is applied to the cell. Second, the SEI growth process is reaction-limited during the first formation charge but becomes diffusion-limited for the remaining life of the cell. Third, during the first formation charge, each electrode sees an extended range of lithium stoichiometries and electrode surface potentials which will never be accessed again for the remaining life of the cell.

We envision that the formation model can be leveraged for improving formation protocol design, electrolyte engineering, cell lifetime simulations, and physics model parameter identification. In a battery manufacturing context, our model could see potential applications as a physics-based digital twin of the formation process.

Overall, the proposed modeling framework enables practical pathways for bridging the electrochemistry of battery formation to macroscopic variables related to battery performance, safety and lifetime.

### 10. Expansion Model Derivations

### 10.1 Reversible Expansion from Intercalation-Induced Electrode Swelling

Unit cell lattice parameters can be converted into a net volume change vᵢ according to:

$${v}_{i} = \frac{{dV}_{i}}{{V}_{i}} , \qquad ( 49 )$$

where Vᵢ is the volume of a unit cell. To relate the experimental data vᵢ to the macroscopically observed cell thickness change, we first define the volume-averaged number of particles along the total length of the electrodes, N̅ₚ, as:

$${\overline{N}}_{p} {=}^{△} \frac{{L}_{i}}{{R}_{i}} \qquad ( 50 )$$

where Lᵢ is the electrode thickness and Rᵢ is the radius of a single electrode particle which is assumed to be spherical. We assume that N̅ₚ remains constant as the particles expand and contract, and hence:

$${\overline{N}}_{p} = \frac{{dL}_{i}}{{dR}_{i}} , \qquad ( 51 )$$

where d_{L}_{ᵢ} is the incremental thickness change of the electrode and dRᵢ is the corresponding electrode particle radius change. Combining Eqs 50 and 51 yields a scaling law to convert from microscopic expansion to macroscopic expansion.

$${dL}_{i} = \frac{{L}_{i}}{{R}_{i}} {dR}_{i} . \qquad ( 52 )$$

Next, we convert vᵢ to radial expansion, dRᵢ, by assuming a spherical particle, in which case:

$${dR}_{i} = \frac{{R}_{i}}{3} {v}_{i} , \qquad ( 53 )$$

where we have substituted the equation of a sphere for particle volume Vᵢ, with the differential form dVᵢ=4πRᵢ²dRᵢ. We can now substitute Eq. 53 into Eq. 52 to arrive at:

$${dL}_{i} {=}^{△} = \frac{{L}_{i}}{3} {v}_{i} . \qquad ( 54 )$$

Finally, the total reversible cell thickness expansion from electrode i is:

$${Δ}_{i} = {N}_{layer} \cdot {dL}_{i} \qquad ( 55 )$$

$$= \frac{{N}_{layers} {L}_{i}}{3} {v}_{i} , \qquad ( 56 )$$

where N_{layers} is the number of electrode layers in the stacked pouch cell configuration.

### 10.2 Irreversible Expansion from SEI Growth

Assuming constant particle density, we have that:

$${ρ}_{SEI} = {dm}_{SEI} / {dV}_{SEI} , \qquad ( 57 )$$

where m_{SEI} is the SEI mass accumulated in kg and ρ_{SEI} is the SEI density in kg/m³, and V_{SEI} is the SEI volume in m³. SEI mass accumulation is proportional to total charge accumulated, Q_{SEI}, according to:

$${dm}_{SEI} = \frac{{M}_{SEI}}{nF} {dQ}_{SEI} , \qquad ( 58 )$$

where M_{SEI} is the molar mass and Q_{SEI}=»I_{SEI}dt is the charge accumulated to form SEI. It follows that:

$${dV}_{SEI} = {V}_{m , SEI} \frac{{dQ}_{SEI}}{nF} . \qquad ( 59 )$$

We can then use 58 and 59 to derive an expression for the SEI thickness on the negative electrode particles:

$${δ}_{SEI} = \frac{{dV}_{SEI}}{N \cdot 4 π {R}_{n}^{2}} \qquad ( 60 )$$

$$= \frac{1}{N \cdot 4 π {R}_{n}^{2}} {V}_{m , SEI} \frac{{dQ}_{SEI}}{nF} \qquad ( 61 )$$

where N is the number of negative electrode particles. Differentiating both sides and substituting I_{SEI}=dQ_{SEI}/dt and j_{SEI}=I_{SEI}/(N·4πRₙ²) yields the expression:

$$\frac{d {δ}_{SEI}}{dt} = {V}_{m , SEI} \frac{{j}_{SEI}}{nF} . \qquad ( 62 )$$

Eq. 52 can then be used to convert the SEI thickness growth into a macroscopic expansion:

$${dL}_{SEI} = \frac{{L}_{n}}{{R}_{n} + {dR}_{n}} {δ}_{SEI} \qquad ( 63 )$$

$$= \frac{{L}_{n}}{{R}_{n} ( 1 + {v}_{n} / 3 )} {δ}_{SEI} , \qquad ( 64 )$$

where we have assumed that the SEI grows on the negative electrode particle with a radius Rₙ+dRₙ. The total irreversible cell thickness expansion is then:

$${δ}_{SEI} = {N}_{layers} \cdot {dL}_{SEI} \qquad ( 65 )$$

$$= \frac{{N}_{layers} {L}_{n}}{{R}_{n} ( 1 + {v}_{n} / 3 )} {δ}_{SEI} , \qquad ( 66 )$$

where N_{layers} is the number of electrode layers in the stacked pouch cell configuration.

### Nomenclature

### Acronyms

CC: constant current
CE: coulombic efficiency
CV: constant voltage
DEC: diethyl carbonate
DMC: dimethyl carbonate
EC: ethylene carbonate
FCE: first cycle efficiency
LEDC: lithium ethylene dicarbonate
LVDC: lithium vinylene dicarbonate
SEI: solid electrolyte interphase
VC: vinylene carbonate
SOC: state of charge

### Subscripts

i: electrode (n or p)
r: SEI reacting species (A, B, . . . )
I: SEI solid reaction product (A′, B′, . . . )
k: cycle number

### Superscripts

o: electrolyte bulk phase

### REFERENCES

1. S. J. An, J. Li, C. Daniel, D. Mohanty, S. Nagpure, and D. L. Wood, “The state of understanding of the lithium-ion-battery graphite solid electrolyte interphase (SEI) and its relationship to formation cycling.” Carbon N.Y., 105, 52 (2016).
2. Y. Liu, R. Zhang, J. Wang, and Y. Wang, “Current and future lithium-ion battery manufacturing.” iScience, 24, 102332 (2021).
3. P. B Balbuena and Y. Wang, Lithium-Ion Batteries: Solid-Electrolyte Interphase (Imperial College Press) (2004).
4. M. B. Pinson and M. Z. Bazant, “Theory of SEI formation in rechargeable batteries: capacity fade, accelerated aging and lifetime prediction.” J. Electrochem. Soc., 16, 0.2 (2012).
5. E. Peled and S. Menkin, “Review—SEI: past, present and future.” J. Electrochem. Soc., 164, A1703 (2017).
6. S. K. Heiskanen, J. Kim, and B. L. Lucht, “Generation and evolution of the solid electrolyte interphase of Lithium-Ion batteries.” Joule, 3, 2322 (2019).
7. R. Petibon, “Study of the reactivity of electrolyte solvents and additives in Li-ion cells and design of new electrolyte blends.” PhD thesis, Dalhousie University (2016).
8. F. Röder, R. D. Braatz, and U. Krewer, “Multi-scale simulation of heterogeneous surface film growth mechanisms in lithium-ion batteries.” J. Electrochem. Soc., 164, E3335 (2017).
9. W. Huang et al., “Evolution of the solid-electrolyte interphase on carbonaceous anodes visualized by atomic-resolution cryogenic electron microscopy.” Nano Lett., 19, 5140 (2019).
10. P. Mohtat, S. Lee, V. Sulzer, J. B. Siegel, and A. G. Stefanopoulou, “Differential expansion and voltage model for Li-ion batteries at practical charging rates.” J. Electrochem. Soc., 167, 110561 (2020).
11. P. Mohtat, S. Lee, J. B. Siegel, and A. G. Stefanopoulou, “Reversible and irreversible expansion of lithium-ion batteries under a wide range of stress factors.” J. Electrochem. Soc., 168, 100520 (2021).
12. S. Pannala, A. Weng, I. Fischer, J. B. Siegel, and A. G. Stefanopoulou, “Low-Cost inductive sensor and fixture kit for measuring battery cell thickness under constant pressure.” IFAC-PapersOnLine, 55, 712 (2022).
13. A. J. Louli, L. D. Ellis, and J. R. Dahn, “Operando pressure measurements reveal solid electrolyte interphase growth to rank Li-ion cell performance.” Joule, 3, 745 (2019).
14. P. Ramadass, B. Haran, P. M. Gomadam, R. White, and B. N. Popov, “Development of first principles capacity fade model for Li-ion cells.” J. Electrochem. Soc., 151, A196 (2004).
15. G. Ning, R. E. White, and B. N. Popov, “A generalized cycle life model of rechargeable Li-ion batteries.” Electrochim. Acta, 51, 2012 (2006).
16. M. Safari, M. Morcrette, A. Teyssot, and C. Delacourt, “Multimodal physics-based aging model for life prediction of Li-ion batteries.” J. Electrochem. Soc., 156, A145 (2008).
17. H. Ekstrom and G. Lindbergh, “A model for predicting capacity fade due to SEI formation in a commercial Graphite/LiFePO₄ cell.” J. Electrochem. Soc., 162, A1003 (2015).
18. H. J. Ploehn, P. Ramadass, and R. E. White, “Solvent diffusion model for aging of Lithium-ion battery cells.” J. Electrochem. Soc., 151, A456 (2004).
19. J. M. Reniers, G. Mulder, and D. A. Howey, “Review and performance comparison of mechanical-chemical degradation models for lithium-ion batteries.” J. Electrochem. Soc., 166, A3189 (2019).
20. N. Kamyab, J. Weidner, and R. E. White, “Mixed mode growth model for the solid electrolyte interphase (SEI).” J. Electrochem. Soc., 166, A334 (2019).
21. C. Kupper, B. Weiβhar, S. Riβmann, and W. G. Bessler, “End-of-life prediction of a lithium-ion battery cell based on mechanistic aging models of the graphite electrode.” J. Electrochem. Soc., 165, A3468 (2018).
22. I. Laresgoiti, S. Käbitz, M. Ecker, and D. U. Sauer, “Modeling mechanical degradation in lithium ion batteries during cycling: solid electrolyte interphase fracture.” J. Power Sources, 300, 112 (2015).
23. F. Brosa Planella et al., “A continuum of physics-based lithium-ion battery models reviewed,” Prog.” Energy Combust. Sci., 4, 042003 (2022).
24. A. A. Wang et al., “Review of parameterisation and a novel database (LiionDB) for continuum Li-ion battery models.” Prog. Energy Combust. Sci., 4, 032004 (2022).
25. S. E. J. O'Kane, W. Ai, G. Madabattula, D. Alonso-Alvarez, R. Timms, V. Sulzer, J. S. Edge, B. Wu, G. J. Offer, and M. Marinescu, “Lithium-ion battery degradation: how to model it.” Phys. Chem. Chem. Phys., 24, 7909 (2022).
26. J. Christensen and J. Newman, “A mathematical model for the Lithium-Ion negativeelectrode solid electrolyte interphase.” J. Electrochem. Soc., 151, A1977 (2004).
27. F. Single, B. Horstmann, and A. Latz, “Dynamics and morphology of solid electrolyte interphase (SEI).” Phys. Chem. Chem. Phys., 18, 17810 (2016).
28. F. Single, B. Horstmann, and A. Latz, “Revealing SEI morphology: in-depth analysis of a modeling approach.” J. Electrochem. Soc., 164, E3132 (2017).
29. L. von Kolzenberg, M. Werres, J. Tetzloff, and B. Horstmann, “Transition between growth of dense and porous films: theory of dual-layer SEI.” Phys. Chem. Chem. Phys., 24, 18469 (2022).
30. P. M. Attia, S. J. Harris, and W. C. Chueh, “Benefits of fast battery formation in a model system.” J. Electrochem. Soc., 168, 050543 (2021).
31. A. Weng, P. Mohtat, P. M. Attia, V. Sulzer, S. Lee, G. Less, and A. G. Stefanopoulou, “Predicting the impact of formation protocols on battery lifetime immediately after manufacturing.” Joule, 5, 1 (2021).
32. L. Guo, D. B. Thornton, M. A. Koronfel, I. E. L. Stephens, and M. P. Ryan, “Degradation in lithium ion battery current collectors.” J. Phys. Energy, 3, 032015 (2021).
33. P. M. Attia, W. C. Chueh, and S. J. Harris, “Revisiting the t 0.5 dependence of SEI growth.” J. Electrochem. Soc., 167, 090535 (2020).
34. B. Rowden and N. Garcia-Araez, “A review of gas evolution in lithium ion batteries.” Energy Reports, 6, 10 (2020).
35. M. Ryan, P. Münster, M. Diehl, J. Enno, B. Markus, M. Winter, and P. Niehoff, “Effect of Li plating during formation of lithium ion batteries on their cycling performance and thermal safety.” J. Power Sources, 484 (2021).
36. S.-H. Kang, W.-S. Yoon, K.-W. Nam, X.-Q. Yang, and D. P. Abraham, “Investigating the first-cycle irreversibility of lithium metal oxide cathodes for Li batteries.” J. Mater. Sci., 43, 4701 (2008).
37. K. Smith, P. Gasper, A. M. Colclasure, Y. Shimonishi, and S. Yoshida, “Lithium ion battery life model with electrode cracking and early-life break-in processes.” J. Electrochem. Soc., 168 (2021).
38. Z. Xu, J. Yang, T. Zhang, Y. Nuli, J. Wang, and S.-I. Hirano, “Silicon microparticle anodes with self-healing multiple network binder.” Joule, 2, 950 (2018).
39. J. Xu, “Critical review on cathode-electrolyte interphase toward high-voltage cathodes for Li-ion batteries.” Nanomicro Lett., 14, 166 (2022).
40. Sungjemmenla, Vineeth, C. B Soni, V Kumar, and Z. W. Seh, “Understanding the cathode-electrolyte interphase in lithium-ion batteries.” Energy Technol., 10, 2200421 (2022).
41. State of Charge Estimation Error due to Parameter Mismatch in a Generalized Explicit Lithium Ion Battery Model, ASME 2011 Dynamic Systems and Control Conference and Bath/ASME Symposium on Fluid Power and Motion Control, Volume 1 of Dynamic Systems and Control Conference, 10 2011.
42. G. L. Plett, Battery Management Systems, Volume I: Battery Modeling (Artech House) (2015).
43. D. Aurbach, M. L. Daroux, P. W. Faguy, and E. Yeager, “Identification of surface films formed on lithium in propylene carbonate solutions.” J. Electrochem. Soc., 134, 1611 (1987).
44. B. Zhang, M. Metzger, S. Solchenbach, M. Payne, S. Meini, H. A. Gasteiger, A. Garsuch, and B. L. Lucht, “Role of 1,3-propane sultone and vinylene carbonate in solid electrolyte interface formation and gas generation.” J. Phys. Chem. C, 119, 11337 (2015).
45. G. V. Zhuang, K. Xu, H. Yang, T. R. Jow, and P. N. Ross Jr, “Lithium ethylene dicarbonate identified as the primary product of chemical and electrochemical reduction of EC in 1.2 M LiPF₆/EC: EMC electrolyte.” J. Phys. Chem. B, 109, 17567 (2005).
46. T. F. Fuller, M. Doyle, and J. Newman, “Simulation and optimization of the dual lithium ion insertion cell.” J. Electrochem. Soc., 141, 1 (1994).
47. X.-G. Yang, Y. Leng, G. Zhang, S. Ge, and C.-Y. Wang, “Modeling of lithium plating induced aging of lithium-ion batteries: transition from linear to nonlinear aging.” J. Power Sources, 360, 28 (2017).
48. B. E. Deal and A. S. Grove, “General relationship for the thermal oxidation of silicon.” J. Appl. Phys., 36, 3770 (1965).
49. V. Sulzer, P. Mohtat, S. Pannala, J. B. Siegel, and A. G. Stefanopoulou, “Accelerated battery lifetime simulations using adaptive inter-cycle extrapolation algorithm.” J. Electrochem. Soc., 168, 120531 (2021).
50. S. Schweidler, L. de Biasi, A. Schiele, P. Hartmann, T. Brezesinski, and J. Janek, “Volume changes of graphite anodes revisited: a combined operando x-ray diffraction and in situ pressure analysis study.” J. Phys. Chem. C, 122, 8829 (2018).
51. J. Li, Z. Zhou, Z. Luo, Z. He, J. Zheng, Y. Li, J. Mao, and K. Dai, “Microcrack generation and modification of Ni-rich cathodes for Li-ion batteries: a review.” Sustain. Mater. Technol., 29, e00305 (2021).
52. J. Keil and A. Jossen, “Electrochemical modeling of linear and nonlinear aging of Lithium-Ion cells.” J. Electrochem. Soc., 167, 110535 (2020).
53. D. J. Pereira, A. M. Aleman, J. W. Weidner, and T. R. Garrick, “A Mechano-Electrochemical battery model that accounts for preferential lithiation inside blended silicon graphite (Si/C) anodes.” J. Electrochem. Soc., 169, 020577 (2022).
54. E. E. Petersen, “Diffusion in a pore of varying cross section.” AlChE J., 4, 343 (1958).
55. D.-W. Chung, M. Ebner, D. R. Ely, V. Wood, and R. Edwin García, “Validity of the bruggeman relation for porous electrodes.” Modell. Simul. Mater. Sci. Eng., 21, 074009 (2013).
56. V. Sulzer, S. G. Marquis, R. Timms, M. Robinson, and S. Jon Chapman, “Python battery mathematical modelling (PyBaMM).” Journal of Open Research Software, 9, 1 (2021).
57. J. M. Reniers and D. A. Howey, “Digital twin of a MWh-scale grid battery system for efficiency and degradation analysis.” Appl. Energy, 336, 120774 (2023).
58. S.-K. Jeong, M. Inaba, R. Mogi, Y. Iriyama, T. Abe, and Z. Ogumi, “Surface film formation on a graphite negative electrode in lithium-ion batteries: atomic force microscopy study on the effects of film-forming additives in propylene carbonate solutions.” Langmuir, 17, 8281 (2001).
59. P. M. Attia, S. Das, S. J. Harris, M. Z. Bazant, and W. C. Chueh, “Electrochemical kinetics of SEI growth on carbon black: part I. Experiments.” J. Electrochem. Soc., 166, E97 (2019).
60. D. Pritzl, S. Solchenbach, M. Wetjen, and H. A. Gasteiger, “Analysis of vinylene carbonate (VC) as additive in Graphite/LiNi_{0.5}Mn_{1.5}O₄ cells.” J. Electrochem. Soc., 164, A2625 (2017).
61. D. Aurbach, K. Gamolsky, B. Markovsky, Y. Gofer, M. Schmidt, and U. Heider, “On the use of vinylene carbonate (VC) as an additive to electrolyte solutions for Li-ion batteries.” Electrochim. Acta, 47, 1423 (2002).
62. H. Haruna, S. Takahashi, and Y. Tanaka, “Accurate consumption analysis of vinylene carbonate as an electrolyte additive in an 18650 lithium-ion battery at the first charge-discharge cycle.” J. Electrochem. Soc., 164, A6278 (2016).
63. Y. Wang, S. Nakamura, K. Tasaki, and P. B. Balbuena, “Theoretical studies to understand surface chemistry on carbon anodes for lithium-ion batteries: how does vinylene carbonate play its role as an electrolyte additive?” J. Am. Chem. Soc., 124, 4408 (2002).
64. H. Ota, Y. Sakata, A. Inoue, and S. Yamaguchi, “Analysis of vinylene carbonate derived SEI layers on graphite anode.” J. Electrochem. Soc., 151, A1659 (2004).
65. A. Weng, J. B. Siegel, and A. Stefanopoulou, “Differential voltage analysis for battery manufacturing process control.” Frontiers in Energy Research, 11, 1 (2023).
66. C. R. Birkl, E. McTurk, M. R. Roberts, P. G. Bruce, and D. A. Howey, “A parametric open circuit voltage model for lithium ion batteries.” J. Electrochem. Soc., 162, A2271 (2015).
67. W. Dreyer, J. Jamnik, C. Guhlke, R. Huth, J. Moškon, and M. Gaberšček, “The thermodynamic origin of hysteresis in insertion batteries,.” Nat. Mater., 9, 448 (2010).
68. S. Hulikal and A. Bower, “On the role of heterogeneity in Phase-Transforming electrodes: Origin of Zero-Current hysteresis.” J. Electrochem. Soc., 164, A1401 (2017).
69. S. Yang, X. Wang, X. Yang, Y. Bai, Z. Liu, H. Shu, and Q. Wei, “Determination of the chemical diffusion coefficient of lithium ions in spherical Li[Ni0.5MN0.3CO0.2]O2.” Electrochim. Acta, 66, 88 (2012).
70. H. Zhou, F. Xin, B. Pei, and M. S. Whittingham, “What limits the capacity of layered oxide cathodes in lithium batteries?” ACS Energy Lett., 4, 1902 (2019).
71. A. Liu, N. Phattharasupakun, M. M. E. Cormier, E. Zsoldos, N. Zhang, E. Lyle, P. Arab, M. Sawangphruk, and J. R. Dahn, “Factors that affect capacity in the low voltage kinetic hindrance region of Ni-Rich positive electrode materials and diffusion measurements from a reinvented approach.” J. Electrochem. Soc., 168, 070503 (2021).
72. C. Mao, S. J. An, H. M. Meyer, J. Li, M. Wood, R. E. Ruther, and D. L. Wood, “Balancing formation time and electrochemical performance of high energy lithium-ion batteries.” J. Power Sources, 402, 107 (2018).
73. C. E. Hendricks, A. N. Mansour, D. A. Fuentevilla, H. Waller, J. K. Ko, and M. G. Pecht, “Copper dissolution in overdischarged lithium-ion cells: X-ray photoelectron spectroscopy and x-ray absorption fine structure analysis.” J. Electrochem. Soc., 167 (2020).
74. A. Eldesoky, M. Bauer, S. Azam, E. Zsoldos, W. Song, R. Weber, S. Hy, M. B. Johnson, M. Metzger, and J. R. Dahn, “Impact of graphite materials on the lifetime of NMC811/Graphite pouch cells: part i. material properties, ARC safety tests, gas generation, and room temperature cycling.” J. Electrochem. Soc., 168, 110543 (2021).
75. S. Das, P. M. Attia, W. C. Chueh, and M. Z. Bazant, “Electrochemical kinetics of SEI growth on carbon black: Part II. Modeling.” J. Electrochem. Soc., 166, E107 (2019).
76. Y. Preger, H. M.Barkholtz,A. Fresquez, D. L.Campbell, B. W. Juba, J.Roman-Kustas, S. R. Ferreira, and B. Chalamala, “Degradation of commercial Lithium-Ion cells as a function of chemistry and cycling conditions.” J. Electrochem. Soc., 167, 120532 (2020).
77. D. L. Wood, J. Li, and S. J. An, “Formation challenges of Lithium-Ion battery manufacturing,.” Joule, 3, 2884 (2019).
78. S. J. An, J. Li, Z. Du, C. Daniel, and D. L. Wood, “Fast formation cycling for lithium ion batteries.” J. Power Sources, 342, 846 (2017).
79. M. Guo, G. Sikha, and R. E. White, “Single-particle model for a lithium-ion cell: thermal behavior.” J. Electrochem. Soc., 158, A122 (2010).
80. S. J. Moura, F. B. Argomedo, R. Klein, A. Mirtabatabaei, and M. Krstic, “Battery state estimation for a single particle model with electrolyte dynamics.” IEEE Trans. Control Syst. Technol., 25, 453 (2017).
81. Z. Chen, D. L. Danilov, R.-A. Eichel, and P. H. L. Notten, “Porous electrode modeling and its applications to li-ion batteries.” Adv. Energy Mater., 12, 2201506 (2022).

The citation of any document or reference is not to be construed as an admission that it is prior art with respect to the present invention.

Thus, the invention provides methods for making electrochemical devices, such as lithium ion batteries and lithium metal batteries.

In light of the principles and example embodiments described and illustrated herein, it will be recognized that the example embodiments can be modified in arrangement and detail without departing from such principles. Also, the foregoing discussion has focused on particular embodiments, but other configurations are also contemplated. In particular, even though expressions such as “in one embodiment”, “in another embodiment,” or the like are used herein, these phrases are meant to generally reference embodiment possibilities, and are not intended to limit the invention to particular embodiment configurations. As used herein, these terms may reference the same or different embodiments that are combinable into other embodiments. As a rule, any embodiment referenced herein is freely combinable with any one or more of the other embodiments referenced herein, and any number of features of different embodiments are combinable with one another, unless indicated otherwise.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein.

1. A method for manufacturing an electrochemical cell including an anode, an electrolyte, and a cathode including cations that move from the cathode to the anode during a charging phase of each of a plurality of cell cycles, wherein the cell undergoes degradation that results in loss of cation inventory during one or more charging phases of the cell cycles, the method comprising:
(a) selecting at least one cell component selected from the group consisting of electrolyte materials, cathode active materials, and anode active materials, the at least one cell component causing the degradation of the cell;
(b) selecting a formation protocol including: (i) a formation charging phase for creating a formed battery cell from a battery cell structure, and (ii) an aging phase for aging the formed battery cell;
(c) calculating a solid electrolyte interphase (SEI) growth process based on the formation protocol and the at least one cell component using a solid electrolyte interphase growth model that predicts consumption of the cations and expansion of the cell; and
(d) determining a property of the electrochemical cell based on the calculated solid electrolyte interphase growth process, wherein the property is selected from the group consisting of predicted end of life, capacity loss, resistance growth, gas generation, and electrode current collector dissolution.

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. A method for monitoring real-time expansion of an electrochemical cell including an anode, an electrolyte, and a cathode including cations that move from the cathode to the anode during a charging phase of each of a plurality of cell cycles, wherein the cell undergoes degradation that results in loss of cation inventory during one or more charging phases of the cell cycles, the method comprising:
(a) selecting at least one cell component selected from the group consisting of electrolyte materials, cathode active materials, and anode active materials, the at least one cell component causing the degradation of the cell;
(b) calculating a solid electrolyte interphase (SEI) growth process based on the at least one cell component using a solid electrolyte interphase growth model that predicts consumption of the cations and expansion of the cell; and
(c) determining real-time expansion of the electrochemical cell based on the calculated solid electrolyte interphase growth process.

19. The method of claim 18 wherein:
step (a) further comprises selecting a formation protocol including: (i) a formation charging phase for creating a formed battery cell from a battery cell structure, and (ii) an aging phase for aging the formed battery cell, and
step (b) further comprises calculating the solid electrolyte interphase (SEI) growth process based on the formation protocol.

20. The method of claim 19 wherein:
the method comprises monitoring real-time expansion during the formation charging phase.

21. The method of claim 20 wherein:
the method comprises monitoring real-time expansion during the aging phase.

22. The method of claim 18 wherein:
step (b) further comprises calculating the solid electrolyte interphase growth process based on measurements of cell expansion.

23. The method of claim 18 wherein:
the solid electrolyte interphase growth model includes an equation used for calculating boosted SEI growth dynamics during the formation charging phase.

24. The method of claim 18 wherein:
the solid electrolyte interphase growth model predicts solid electrolyte interphase film growth dynamics under multiple reacting species.

25. The method of claim 18 wherein:
the cell component is an electrolyte, and
the solid electrolyte interphase growth model predicts consumption of a solvent of the electrolyte.

26. The method of claim 18 wherein:
the cell component is an electrolyte, and
the solid electrolyte interphase growth model predicts consumption of an additive of the electrolyte.

27. The method of claim 18 wherein:
the expansion of the cell includes reversible expansion from intercalation-induced electrode swelling and irreversible expansion from SEI growth.

28. The method of claim 18 wherein:
the solid electrolyte interphase growth model predicts solid electrolyte interphase passivation properties.

29. The method of claim 18 wherein:
the solid electrolyte interphase growth model predicts measured voltages.

30. The method of claim 18 wherein:
the solid electrolyte interphase growth model predicts coulombic efficiencies.

31. The method of claim 18 wherein:
the solid electrolyte interphase growth model predicts a dQ/dV curve during the formation charging phase.

32. The method of claim 18 wherein:
the solid electrolyte interphase growth model predicts a first-cycle efficiency.

33. The method of claim 18 wherein:
the solid electrolyte interphase growth model predicts cell thickness changes.

34. A method for predicting a property of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) selecting at least one cell component selected from the group consisting of electrolyte materials, cathode active materials, and anode active materials, the at least one cell component causing the degradation of the cell;
(b) calculating a solid electrolyte interphase (SEI) growth process based on the at least one cell component using a solid electrolyte interphase growth model that predicts consumption of the cations and expansion of the cell; and
(c) determining a property of the electrochemical cell based on the calculated solid electrolyte interphase growth process, wherein the property is selected from the group consisting of predicted end of life, capacity loss, resistance growth, gas generation, and electrode current collector dissolution.

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. A method in a data processing system comprising at least one processor and at least one memory, the at least one memory comprising instructions executed by the at least one processor to implement an electrochemical cell property prediction system, wherein the electrochemical cell includes an anode, an electrolyte, and a cathode including cations that move from the cathode to the anode during a charging phase of each of a plurality of cell cycles, wherein the cell undergoes degradation that results in loss of cation inventory during one or more charging phases of the cell cycles, the method comprising, the method comprising:
(a) receiving a selection of at least one cell component selected from the group consisting of electrolyte materials, cathode active materials, and anode active materials, the at least one cell component causing the degradation of the cell;
(b) calculating a solid electrolyte interphase (SEI) growth process based on the at least one cell component using a solid electrolyte interphase growth model that predicts consumption of the cations and expansion of the cell; and
(c) determining a property of the electrochemical cell based on the calculated solid electrolyte interphase growth process.

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)

69. (canceled)

70. (canceled)

71. (canceled)

72. (canceled)

73. (canceled)

74. (canceled)

75. (canceled)

76. The method of claim 18 wherein:
the cations are lithium cations.

77. (canceled)

78. (canceled)

79. (canceled)

80. (canceled)

81. (canceled)

82. (canceled)

83. (canceled)

84. (canceled)
